(19) United States
(12) Patent Application Publication
(10) Pub. No.: US 2013/0070172 A1
(43) Pub. Date: Mar. 21, 2013

(54) TELEVISION RECEIVER AND ELECTRONIC DEVICE

(71) Applicant: Toshio OOE, Tokyo (JP)

(72) Inventor: Toshio OOE, Tokyo (JP)

(73) Assignee: KABUSHIKI KAISHA TOSHIBA, Tokyo (JP)

(21) Appl. No.: 13/525,118

(22) Filed: Jun. 15, 2012

(30) Foreign Application Priority Data
Sep. 15, 2011 (JP) 2011-202457

(51) Int. Cl. H04N 5/64; H05K 7/20

(52) U.S. Cl. 348/843; 361/695; 348/E05.128

(57) ABSTRACT

According to an embodiment, a television receiver includes a display device, a housing, a stand, a circuit board, a second wall, a fan, and a heat dissipater. The display device includes a display screen. The housing includes a first wall covering a back surface of the display screen. The circuit board is arranged between the display device and the first wall. The second wall includes an opening positioned in an eccentric manner in a direction toward a side opposite the stand with respect to a center portion of the display screen. The second wall is arranged between the display device and a surface of the circuit board opposite a surface on which a heating element is mounted. The second wall covers the back surface with a gap therebetween. The fan is arranged between the first wall and the second wall, and includes an air inlet.

### CROSS-REFERENCE TO RELATED APPLICATIONS

This application is based upon and claims the benefit of priority from Japanese Patent Application No. 2011-202457, filed on Sep. 15, 2011; the entire contents of which are incorporated herein by reference.

### FIELD

Embodiments described herein relate generally to a television receiver and an electronic device.

### BACKGROUND

Conventionally widely known are electronic devices capable of suppressing a rise in temperature by an air stream in a housing that houses a display device.

In such an electronic device including a television receiver, it is desired to suppress a rise in temperature more efficiently on the back surface side of the display device.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary perspective view of a television receiver as viewed from a front thereof, according to an embodiment;

FIG. 2 is an exemplary perspective view of the television receiver as viewed from a back thereof in the embodiment;

FIG. 3 is an exemplary perspective view of the television receiver as viewed from a side thereof in the embodiment;

FIG. 4 is an exemplary perspective view of the television receiver as viewed from a side thereof at a different angle from that in FIG. 3, in the embodiment;

FIG. 5 is an exemplary perspective view of a part of a lower portion of a housing of the television receiver as viewed from a lower side thereof, in the embodiment;

FIG. 6 is an exemplary perspective view of a part of the back surface of the housing of the television receiver as viewed from the lower side thereof, in the embodiment;

FIG. 7 is an exemplary back view of a portion to which an air outlet is provided on the back surface of the housing of the television receiver in the embodiment;

FIG. 8 is an exemplary perspective view of an internal configuration of the television receiver in the embodiment;

FIG. 9 is an exemplary perspective view of a state in which a fan, a fifth housing member, and a module are removed from the internal configuration illustrated in FIG. 8, in the embodiment;

FIG. 10 is an exemplary cross sectional view taken along line X-X in FIG. 1, in the embodiment;

FIG. 11 is an exemplary back view of a display device of the television receiver in the embodiment;

FIG. 12 is an exemplary perspective view of a third housing member of the television receiver in the embodiment;

FIG. 13 is an exemplary plan view of a part of the internal configuration of the television receiver in the embodiment;

FIG. 14 is an exemplary perspective view of a first housing member and the display device of the television receiver as viewed from the back, in the embodiment;

FIG. 15 is an exemplary perspective view of the first housing member, the display device, and the third housing member of the television receiver as viewed from the back, in the embodiment;

FIG. 16 is an exemplary perspective view of the first housing member, the display device, and the third housing member of the television receiver as viewed from the back at a different angle from that in FIG. 14, in the embodiment;

FIG. 17 is an exemplary perspective view of a part of the third member of the television receiver in the embodiment;

FIG. 18 is an exemplary perspective view of a state in which a clip is attached to the third housing member illustrated in FIG. 16 in the embodiment;

FIG. 19 is an exemplary perspective view of the clip of the television receiver in the embodiment;

FIG. 20 is an exemplary perspective view of a camera module of the television receiver in the embodiment;

FIG. 21 is an exemplary perspective view of a portion in which the camera module is supported in the first housing member of the television receiver in the embodiment;

FIG. 22 is an exemplary perspective view of a portion in which an antenna is supported in the third housing member of the television receiver in the embodiment;

FIG. 23 is an exemplary back view of a coupling portion of the housing and a support in the television receiver in the embodiment;

FIG. 24 is an exemplary perspective view of the coupling portion of the housing and the support in the television receiver in the embodiment;

FIG. 25 is an exemplary exploded perspective view of the coupling portion of the housing and the support in the television receiver in the embodiment;

FIG. 26 is an exemplary perspective view of a part of a second housing member and the fifth housing member of the television receiver in the embodiment;

FIG. 27 is an exemplary perspective view of the fifth housing member of the television receiver as viewed from the back thereof, in the embodiment;

FIG. 28 is an exemplary perspective view of the fifth housing member of the television receiver as viewed from the front in the embodiment;

FIG. 29 is an exemplary perspective view of the support and a hinge of the television receiver in the embodiment;

FIG. 30 is an exemplary perspective view of a part of the support of the television receiver in the embodiment;

FIG. 31 is an exemplary cross sectional view taken along line XXXI-XXXI in FIG. 29 in the embodiment;

FIG. 32 is an exemplary perspective view of a first supporting member of the television receiver as viewed from the upper side thereof, in the embodiment;

FIG. 33 is an exemplary perspective view of a part of the first supporting member of the television receiver as viewed from the upper side, in the embodiment;

FIG. 34 is an exemplary perspective view of a second supporting member of the television receiver as viewed from the bottom side in the embodiment;

FIG. 35 is an exemplary perspective view of a third supporting member of the television receiver as viewed from the upper side, in the embodiment;

FIG. 36 is an exemplary perspective view of a part of a state in which the third supporting member overlaps the second supporting member of the television receiver in the embodiment viewed from the back;

FIG. 37 is an exemplary side view of a sixth supporting member and a speaker of the television receiver in the embodiment;

FIG. 38 is an exemplary side view of the support and the housing of the television receiver in the embodiment;

FIG. 39 is an exemplary plan view (back view) of an air inlet of a fan and an opening provided to the third housing member of a television receiver according to a modification of the embodiment;

FIG. 40 is an exemplary plan view (back view) of an air inlet of a fan and an opening provided to the third housing member of a television receiver according to another modification of the embodiment; and

FIG. 41 is an exemplary plan view (back view) of an air inlet of a fan and an opening provided to the third housing member of a television receiver according to still another modification of the embodiment.

### DETAILED DESCRIPTION

In general, according to one embodiment, a television receiver comprises a display device, a housing, a stand, a circuit board, a second wall, a fan, and a heat dissipater. The display device comprises a display screen and a back surface opposite the display screen. The housing comprises a first wall covering the back surface, and houses at least a part of the display device. The stand is configured to be connected to the housing, and supports the housing. The circuit board comprises a surface on which a heating element is mounted, and is configured to be arranged between the display device and the first wall. The second wall comprises an opening positioned in an eccentric manner in a direction toward a side opposite the stand with respect to a center portion of the display screen. The second wall is arranged between the display device and a surface of the circuit board opposite the surface on which the heating element is mounted. The second wall is configured to cover the back surface with a gap therebetween. The fan is arranged between the first wall and the second wall, and comprises an air inlet overlapping with at least a part of the opening. The heat dissipater is configured to be thermally connected to the heating element, and to receive exhaust air from the fan.

Exemplary embodiments and modifications described below comprise components similar to each other. Therefore, in the description below, common numerals are assigned to similar components, and overlapping explanation thereof will be omitted. Furthermore, in the drawings, directions (an X direction, a Y direction, and a Z direction) are illustrated for convenience. The X direction is a longitudinal direction with respect to a display screen 4a in a housing 3 of a television receiver 1 viewed from the front, the Y direction is a lateral direction with respect to the display screen 4a viewed from the front, and the Z direction is a front-back direction (depth direction or thickness direction of the housing 3) with respect to the display screen 4a viewed from the front. The X direction, the Y direction, and the Z direction are orthogonal to one another.

In the embodiments below, an electronic device is embodied as a television receiver, for example. However, the electronic device according to the present embodiment is not limited thereto. The electronic device according to the present embodiment can be embodied as various types of electronic devices, such as a tablet or slate personal computer, a smartphone, a smart television, a smartbook, a mobile phone, a personal digital assistant (PDA), an image display, and a video phone.

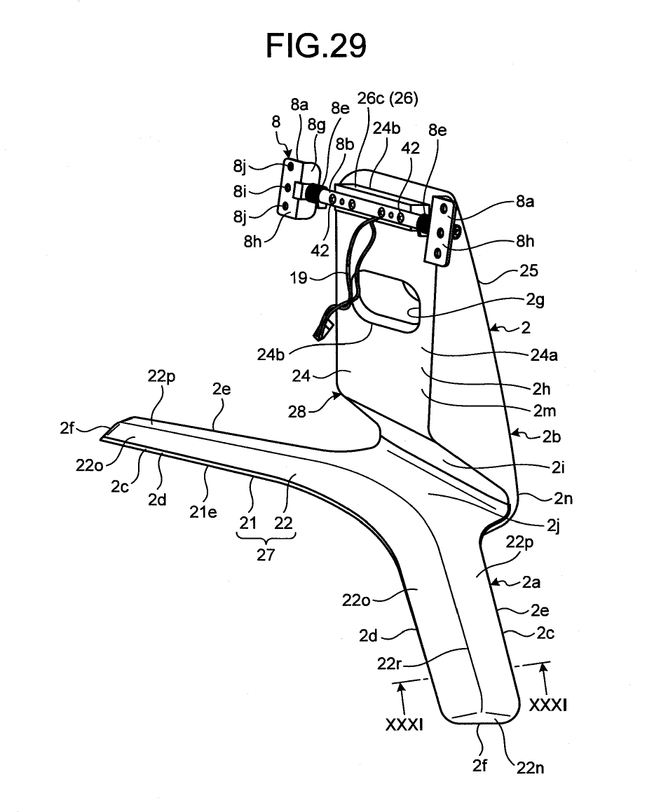

The television receiver 1 comprises a support 2 (a stand, a stand, or a leg) and the housing 3. The housing 3 houses at least a part of a display device 4. The support 2 supports the housing 3. In the present embodiment, for example, the support 2 supports the housing 3 in a rotatable manner via a hinge 8 (refer to FIG. 29). In the present embodiment, for example, the hinge 8 changes the angle of the display screen 4a in the vertical direction. In other words, the hinge 8 can adjust a tilt. The support 2 can support the housing 3 so as to allow the housing 3 to rotate (pivot or swivel, for example) in another direction.

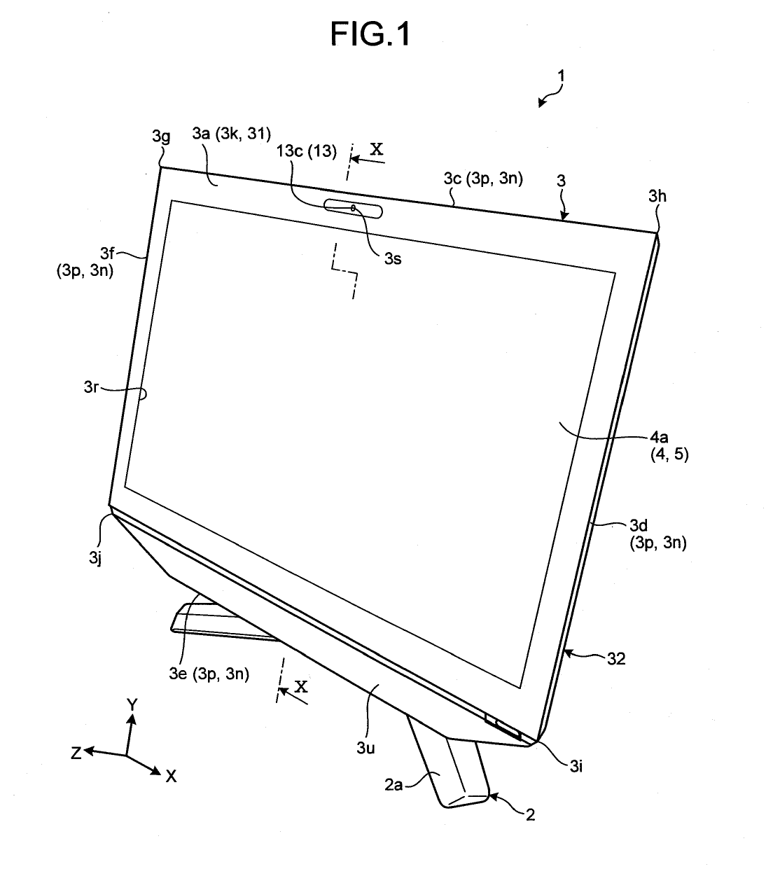

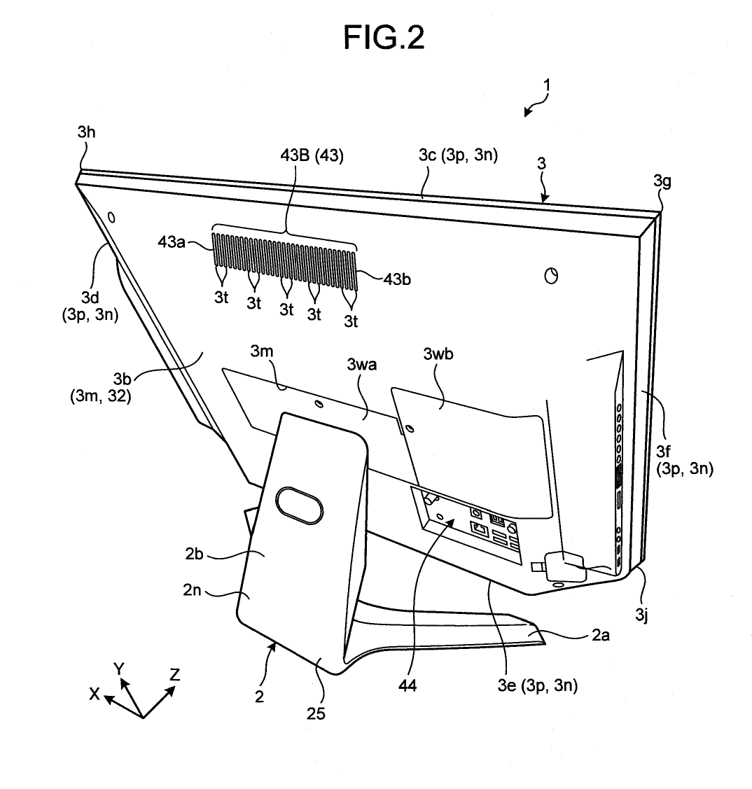

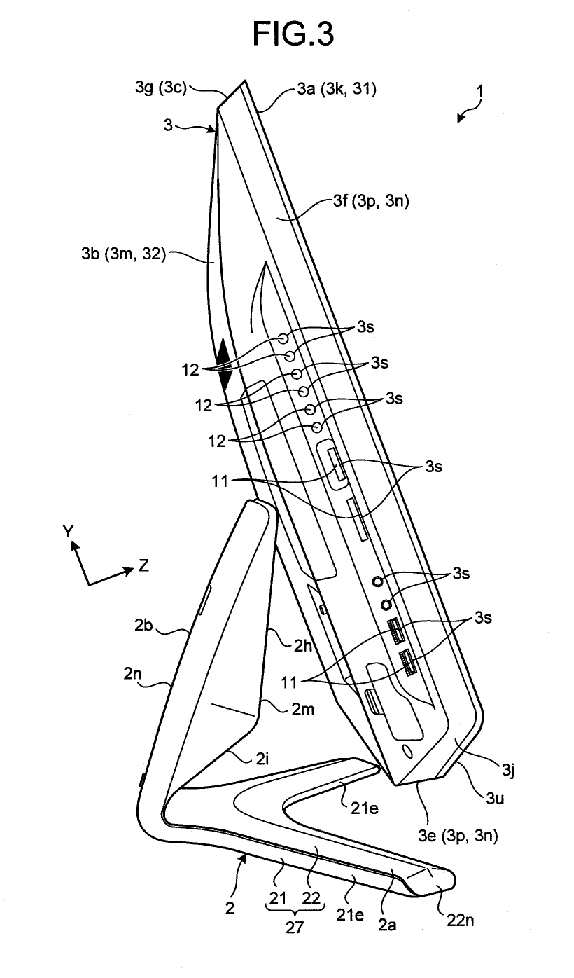

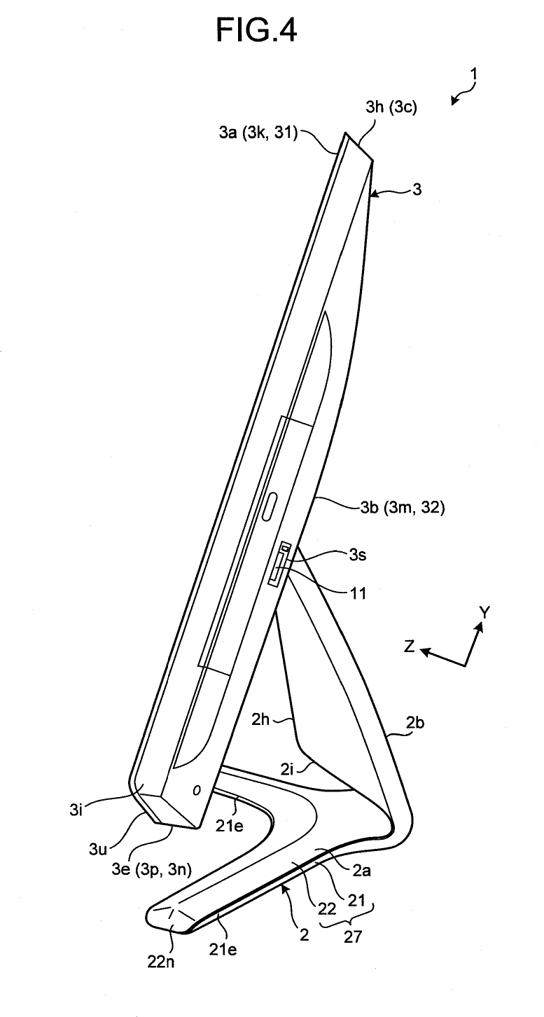

In the present embodiment, for example, the housing 3 of the television receiver 1 is formed in a rectangular shape (an oblong shape in the present embodiment, for example) viewed from the front and the back as illustrated in FIGS. 1 to 4. Furthermore, in the present embodiment, for example, the housing 3 is formed in a flat rectangular parallelepiped shape that has a small width in the front-back direction as illustrated in FIGS. 3 and 4. The housing 3 comprises a front surface 3a (a front face, a surface, a first surface, or a first surface portion) and a rear surface 3b (a back surface, a surface, a second surface, or a second surface portion) opposite thereto. The front surface 3a and the rear surface 3b are approximately parallel to each other. Furthermore, as illustrated in FIGS. 1 and 2, the housing 3 comprises four ends 3c to 3f (sides or edges) and four corners 3g to 3j (peaks, curves, or ends) viewed from the front. The ends 3c and 3e are examples of a long side, and the ends 3d and 3f are examples of a short side.

The housing 3 further comprises a wall 3k (a first section, a plate, a frame, a front wall, a face wall, or a top wall) comprising the front surface 3a and a wall 3m (a second section, a plate, a rear wall, a back wall, or a bottom wall) comprising the rear surface 3b. The walls 3k and 3m are in a rectangular shape (an oblong shape in the present embodiment, for example). Furthermore, the housing 3 comprises four walls 3n (third sections, plates, side walls, end walls, standing walls, or extending portions) comprising a side surface 3p (a surface, a peripheral surface, or a third surface) extending between the wall 3k and the wall 3m. The wall 3k has an opening 3r in a rectangular shape, for example. Therefore, the wall 3k is in a rectangular shape and a frame shape. The wall 3m is an example of a first wall.

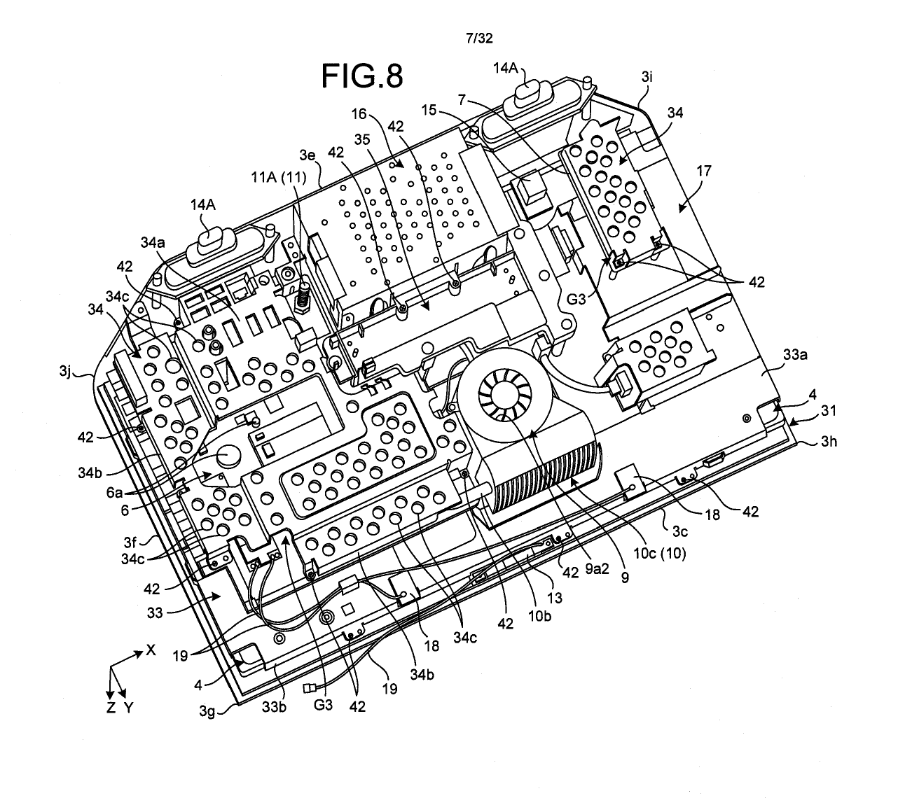

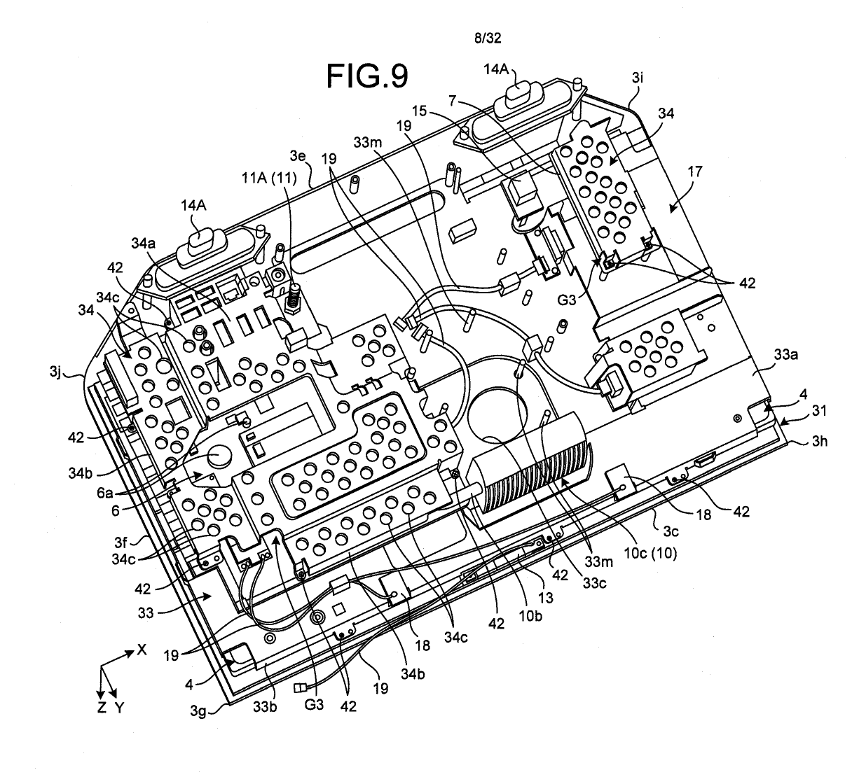

Furthermore, the housing 3 can be configured by combining a plurality of components (divided parts). In the present embodiment, for example, the housing 3 comprises a first housing member 31 (a first section, a front side member, a mask, a mask portion, a cover, a front cover, a cover portion, or a first area) containing at least the wall 3k and a second housing member 32 (a second section, a rear side member, a base, a base portion, a bottom, a bottom portion, a cover, a rear cover, a cover portion, or a second area) containing at least the wall 3m. The wall 3n is contained in at least one of the first housing member 31 and the second housing member 32 (e.g., in the second member 32). In the present embodiment, as illustrated in FIGS. 8 and 9, the housing 3 comprises the following housing members arranged between the first housing member 31 and the second housing member 32 in addition to the first housing member 31 and the second housing member 32: a third housing member 33 (a third section, a middle member, a dividing member, a barrier member, a wall member, an intervening member, an inner plate, a middle plate, a middle frame, or a third area); a fourth housing member 34 (a fourth section, a middle member, a dividing member, a barrier member, a wall member, an intervening member, a covering member, a shield, or a fourth area); and a fifth housing member 35 (a fifth section, a rigid member, a strengthening member, a bracket, a metal member, a casting member, a metal forming member, a die casting component, or a fifth area).

The housing 3 can be made of a metal material, a synthetic resin material, and the like. The third housing member 33 and the fourth housing member 34, for example, can be made of a material having relatively high rigidity (e.g., a metal material, such as stainless steel, a magnesium alloy, and an aluminum alloy). The fifth housing member 35 can be made of a material having relatively high rigidity (e.g., a metal material such as aluminum alloy). The fifth housing member 35 can be produced by die casting, for example. By contrast, the first housing member 31 and the second housing member 32 can be made of a material having relatively low rigidity (a material having lower rigidity than those of the third housing member 33, the fourth housing member 34, and the fifth housing member 35, such as a synthetic resin material). Portions facing the inside of the housing 3 in the first housing member 31 and the second housing member 32 can comprise a wall (a protruding portion or a protruding wall, which is not illustrated) such as a rib. The wall can make the rigidity of the housing 3 higher.

In the present embodiment, for example, a connector 11 and an operating module 12 are provided to the rear surface 3b and the side surface 3p of the housing 3 as illustrated in FIGS. 2 to 4. The connector 11 can be a connector for a power cable, a universal serial bus (USB) connector, a card connector, or a connector for earphones and a microphone, for example. The operating module 12 can be a push button, a push switch, a slide switch, a pointing device, or a dial, for example. Furthermore, as illustrated in FIG. 1, a camera module 13 (an imaging device) can be provided to the front surface 3a. The connector 11, the operating module 12, and the camera module 13 (a camera 13c) are exposed through openings 3s provided to the walls 3k, 3m, and 3n of the housing 3. In the present embodiment, for example, the connector 11 on the rear surface 3b is arranged in a recess 44 provided to the wall 3b as illustrated in FIG. 6. The recess 44 is formed in a rectangular shape (an oblong shape in the present embodiment, for example) viewed from the back (from the rear). The recess 44 is formed of a bottom wall 44a and a side wall 44b. The side wall 44b extends between the bottom wall 44a and the wall 3b. Arrangement of the recess 44 in this manner reduces a protruding amount of a connector (not illustrated) connected to the connector 11 from the housing 3, thereby preventing the connector from coming off, for example.

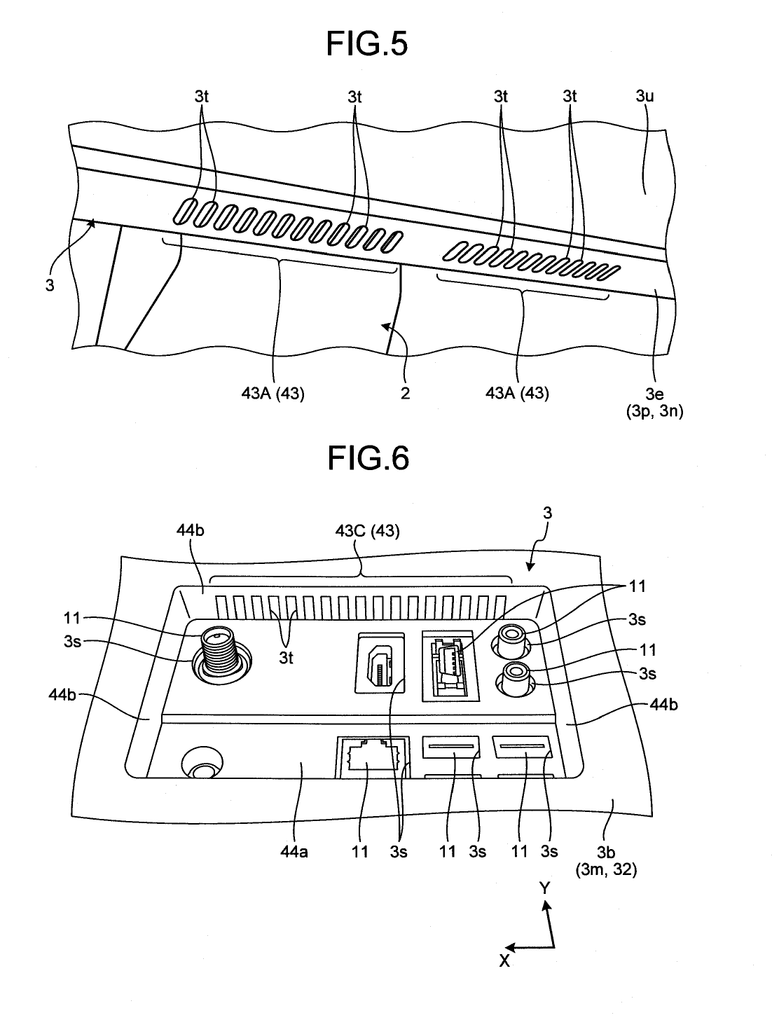

In the present embodiment, for example, a vent 43 (an opening) is provided to the rear surface 3b and the side surface 3p of the housing 3 as illustrated in FIGS. 5 to 7. The vent 43 introduces and exhausts air used for suppressing a rise in temperature (cooling) of a component 6a (an electrical component, an electronic component, an element, a module, or a chip, refer to FIGS. 8 and 9) provided to the display device 4 and boards 6 and 7 (circuit boards, printed boards, or printed wiring boards) in the housing 3, for example. In the present embodiment, for example, a vent 43A (43) functioning as an inlet that introduces air is provided to the side surface 3p (wall 3n or end 3e). Furthermore, a vent 43B (43) functioning as an outlet that exhausts the air is provided to the rear surface 3b (wall 3m). In the present embodiment, for example, the vent 43 is provided as a portion composed of a plurality of small apertures 3t (slits) on the walls 3m and 3n. The inside of the housing 3 may be cooled by forced cooling using a fan 9 and a cooling device 10 (refer to FIG. 9), or may be cooled by natural cooling (convection cooling). The vent 43 can be provided to the front surface 3a.

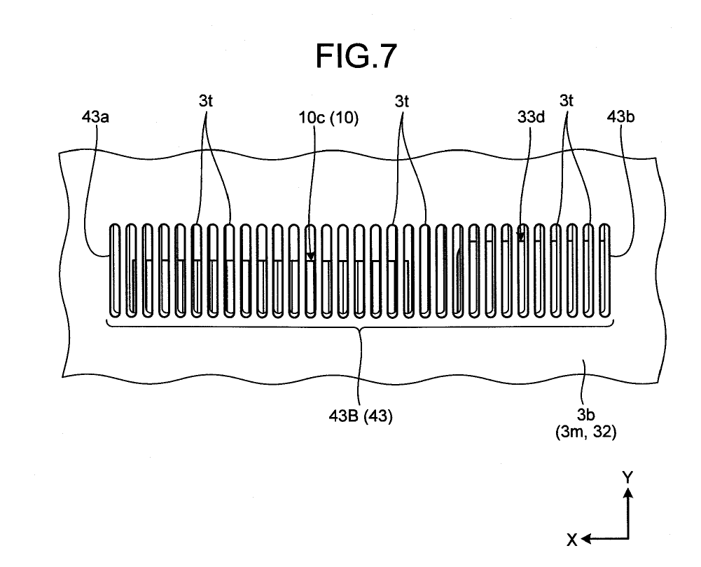

Specifically, in the present embodiment, for example, the vent 43A functioning as an inlet (an air inlet or an inlet port) is provided to the wall 3n of the end 3e on the lower side of the housing 3 as illustrated in FIG. 5. Furthermore, in the present embodiment, for example, the vent 43B functioning as an outlet (an air outlet or an outlet port) is provided to the wall 3b of the end 3c on the upper side of the housing 3 as illustrated in FIGS. 2 and 7. The end 3c extends between the two corners 3g and 3h positioned on the upper side. With such a configuration, an air stream flowing from the lower side to the upper side is likely to be generated in the housing 3. Natural convection caused by heat travels from the lower side to the upper side. Therefore, the vent 43 (opening) is provided to the end 3c and the end 3e on the upper side and the lower side, respectively, of the housing 3, thereby making it possible to achieve smoother ventilation. Furthermore, in the present embodiment, for example, a vent 43C functioning as an inlet is provided to the side wall 44b of the recess 44 as illustrated in FIG. 6. Arrangement of the vent 43 on the side wall 44b of the recess 44 in this manner makes the vent 43 inconspicuous, for example. Furthermore, arrangement of the vent 43 on the wall 3n and the side wall 44b facing downward not only makes the vent 43 inconspicuous, but also prevents dust or the like from entering the housing 3 through the vent 43, for example. Furthermore, by providing the vent 43 to the wall 3n and the side wall 44b extending along the thickness direction of the housing 3, for example, an air stream flowing in a direction along the walls 3m and 3k is more likely to be generated in the housing 3 by the air introduced from the vent 43 compared with the case where the vent 43 is provided to the walls 3m and 3k extending along a direction intersecting with the thickness direction of the housing 3. In the present embodiment, the vent 43B provided to the end 3c is an example of a second opening, the vent 43A provided to the end 3e is an example of a fourth opening, and the vent 43C provided to the side wall 44b is an example of a sixth opening.

In the present embodiment, for example, the display device 4 (a display module, a display, or a panel) is housed between the first housing member 31 and the third housing member 33 as illustrated in FIGS. 8 to 10. As illustrated in FIG. 1, the display screen 4a arranged on the front surface 3a side of the display device 4 is exposed forward (outside) of the housing 3 through the opening 3r. A user can visually confirm the display screen 4a from the front side through the opening 3r. The display device 4 is formed in a rectangular shape (an oblong shape in the present embodiment, for example) viewed from the front. Furthermore, the display device 4 is formed in a flat rectangular parallelepiped shape that has a small width in the front-back direction. The display device 4 is a liquid crystal display (LCD) or an organic electro-luminescent display (OELD), for example.

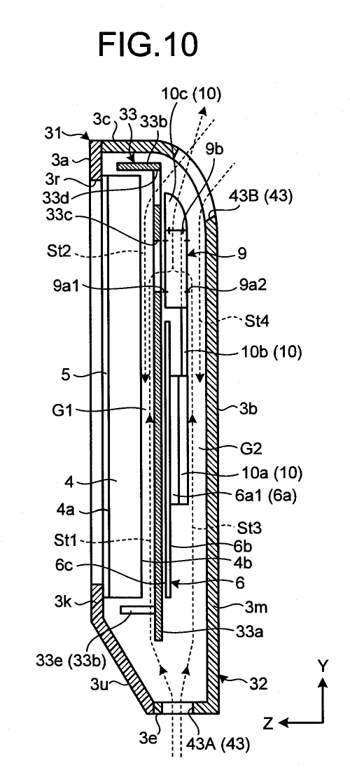

In the present embodiment, for example, the front side (face side or wall 3k side) of the display device 4 is provided with an input operation panel 5 (e.g., a touch panel, a touch sensor, and an operation surface) as illustrated in FIG. 10. The input operation panel 5 is transparent and is formed in a relatively thin rectangular shape, and covers the display screen 4a. An operator (e.g., a user) uses his/her finger or a component (e.g., a stylus, which is not illustrated) to perform an operation, such as a touch, a press, a slide, and a motion of the finger, the stylus, or the like near the input operation panel 5, with respect to the input operation panel 5, thereby performing input processing. Furthermore, light output from the display screen 4a of the display device 4 passes through the input operation panel 5, and is output forward (outside) of the housing 3 through the opening 3r of the wall 3k. The input operation panel 5 is an example of an input module.

In the present embodiment, for example, a plurality of boards 6 and 7 (the board 6 alone is illustrated in FIG. 10) are housed on the rear side (other side, back side, wall 3m side, or side opposite the display screen 4a) of the display device 4 in the housing 3 as illustrated in FIG. 10. Specifically, in the present embodiment, for example, the boards 6 and 7 are housed between the wall 3m of the second housing member 32 and a wall 33a of the third housing member 33. As illustrated in FIGS. 8 and 9, the boards 6 and 7 are arranged in different positions, and are provided in a manner parallel to the display device 4. Furthermore, the boards 6 and 7 are provided in a manner separated from the walls 3k, 3m, 3n, and the like, that is, with a space (a gap) interposed between the boards 6 and 7 and the walls 3k, 3m, 3n, and the like. It is preferable that the boards 6 and 7 be arranged side by side along the display device 4, and be not overlapped with each other in the thickness direction of the housing 3. The boards 6 and 7 are fixed to the housing 3 by a fixture 42 such as a screw. The board 6 comprises a surface 6b to which a heating element 6a1 is provided and a surface 6c opposite thereto. The wall 33a of the third housing member 33 is positioned between the surface 6c and a back surface 4b of the display device 4.

In the present embodiment, for example, a plurality of components 6a (refer to FIGS. 8 and 9, a part of which is illustrated in FIGS. 8 and 9) can be mounted on the board 6 (first board, first circuit board, control board, or main board). Examples of the components 6a include a central processing unit (CPU), a graphic controller, a power circuit component, a platform controller hub (PCH), a memory slot connector, an LCD connector, an input/output (I/O) connector, a power coil, an element, and a connector. The components 6a include the heating element 6a1. The component 6a (heating element 6a1) that generates a large amount of heat can be provided with the cooling device 10. The cooling device 10 comprises a heat receiving module 10a (e.g., a heat sink), a heat transfer module 10b (e.g., a heat pipe), a heat dissipater 10c, and the fan 9. The heat dissipater 10c is thermally connected to the heating element 6a1 via the heat receiving module 10a and the heat transfer module 10b. The board 6 and the components 6a constitute at least a part of a control circuit (not illustrated). The control circuit can comprise an image signal processing circuit, a first tuner, a high-definition multimedia interface (HDMI) signal processor, an audio video (AV) input terminal, a remote-control signal receiver, a controller, a selector, an on-screen display interface, a storage module (e.g., a read-only memory (ROM), a random access memory (RAM), a hard disk drive (HDD), and a solid state drive (SSD)), and a voice signal processing circuit, for example. The control circuit controls output of an image (a moving image, a still image, or the like) by the display screen 4a of the display device 4, output of sound by a speaker (not illustrated), emission of light by a light emitting diode (LED, which is not illustrated), for example. The display device 4, the speaker, the LED, and the like are examples of an output module.

In the present embodiment, for example, circuits required for operating as the television receiver 1 are provided to the board 7 (second board, second circuit board, sub board, or tuner board). Examples of the circuits include a second tuner, an HDMI signal processor, a selector, and an on-screen display interface, for example. In the present embodiment, for example, the tuners are provided to the boards 6 and 7. As a result, it is possible to switch the boards 6 and 7 and the circuits to operate between the case where the television receiver 1 operates as a personal computer and a television receiver and the case where the television receiver 1 operates not as a personal computer but as a television receiver, for example. Therefore, it is possible to further reduce power consumption in the television receiver 1, for example. The boards 6 and 7 comprise the connectors 11 into which a card (an ID card or an IC card) for causing the tuner to operate effectively is inserted. The connectors 11 are exposed on the ends 3d and 3f on the left and right sides of the housing 3. This configuration allows the user to confirm that (whether) a card is inserted into each of the connectors 11, for example.

In the present embodiment, for example, the first housing member 31 is formed in a rectangular shape (an oblong shape in the present embodiment, for example) and in a frame shape as viewed from the front and the back as illustrated in FIG. 1. The opening 3r is provided to the center of the first housing member 31. The wall 3k and the front surface 3a serving as a periphery of the opening 3r are formed in a strip-plate shape. Furthermore, the first housing member 31 covers edges (peripheries) of the display device 4 and the input operation panel 5 from the front side. Thus, the first housing member 31 is an example of a bezel (front bezel). Furthermore, the first housing member 31 is an example of a framework (shell).

In the present embodiment, for example, a speaker 14A (e.g., a speaker system, a full-range speaker, and a tweeter) is attached to the end 3e on the lower side of the first housing member 31 as illustrated in FIGS. 8 and 9. Furthermore, in the present embodiment, for example, the end 3e to which the speaker 14A is provided in the first housing member 31 comprises an inclined surface 3u extending rearward as the surface extends downward as illustrated in FIGS. 1, 3, and 4. The inclined surface 3u is unlikely to be seen from obliquely above, for example. Therefore, even if the portion to which the speaker 14A is provided projects downward from the portion to which the opening 3r is provided as in the present embodiment, for example, it is possible to prevent the front surface 3a from appearing to project downward compared with the case where the inclined surface 3u is not provided.

In the present embodiment, for example, the second housing member 32 is formed in a rectangular shape (an oblong shape in the present embodiment, for example) viewed from the front and the back as illustrated in FIG. 2. Furthermore, the second housing member 32 is formed in a plate shape as a whole. Specifically, the second housing member 32 comprises the wall 3m and the wall 3n. The wall 3n stands from the wall 3m at a periphery of the wall 3m. The (wall 3m of the) second housing member 32 covers the display device 4, the boards 6 and 7, the third housing member 33, the fourth housing member 34, and the fifth housing member 35 from the rear. Thus, the second housing member 32 is an example of a framework (shell). Furthermore, the wall 3m is an example of the first wall.

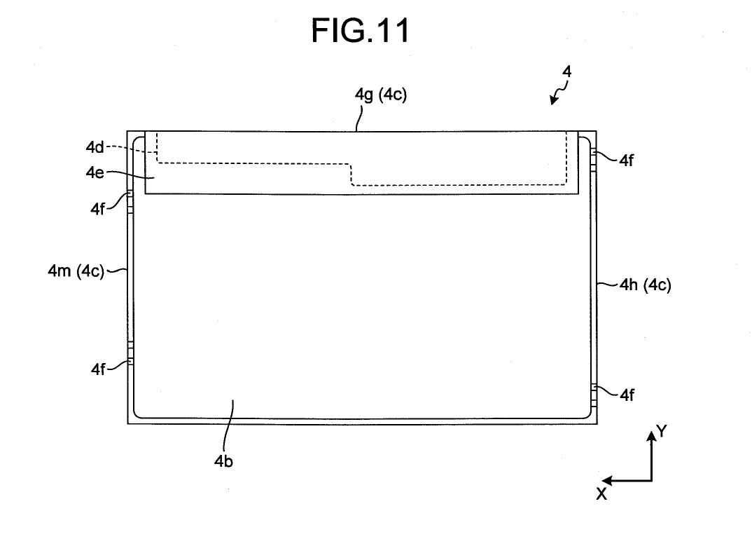

In the present embodiment, for example, the display device 4 is formed in a rectangular shape (an oblong shape in the present embodiment, for example) viewed from the front and the back. Furthermore, in the present embodiment, for example, the display device 4 is formed in a flat rectangular parallelepiped shape that has a small width in the front-back direction. In the present embodiment, for example, no opening (hole, cutout, and the like) is provided to the back surface 4b (rear surface) of the display device 4 as illustrated in FIG. 11. The back surface 4b is entirely covered with a plate (a wall or a metal plate), and is formed as a flat plane. In the present embodiment, for example, a board 4d (circuit board) comprising a circuit for causing the display device 4 to operate is provided along an end 4g (an upper end in the present embodiment, for example) of the display device 4 on the back surface 4b. The board 4d is covered with a covering module 4e (a cover, a film, or an insulator).

In the present embodiment, for example, the back surface 4b of the display device 4 is covered with the wall 33a of the third housing member 33 as illustrated in FIGS. 8 to 10. Specifically, as illustrated in FIGS. 8, 9, and 12, the third housing member 33 is formed in a plate shape as a whole. The third housing member 33 comprises the wall 33a and a wall 33b. The wall 33a is formed in a rectangular plate shape, and covers the back surface 4b of the display device 4. As illustrated in FIG. 10, a gap G1 is formed between the wall 33a and the back surface 4b. In other words, the wall 33a is arranged on the rear (rear side or back side) of the back surface 4b with a space interposed therebetween. The wall 33a is an example of a second wall (a dividing wall, a plate, a lateral wall, or a base). Furthermore, the wall 33b stands from the wall 33a at a periphery of the wall 33a. The wall 33b is an example of a third wall (a side wall, a vertical wall, a standing wall, or a peripheral wall). The wall 33a has openings 33c and 33d. The openings 33c and 33d connect a space in front of the wall 33a (on the display device 4 side) and a space behind the wall 33a (on the side opposite the display device 4). In the present embodiment, for example, the edge of the opening 33d is folded back, whereby a sharp edge is prevented from occurring on the edge. This configuration prevents a harness 19 or the like from being damaged, for example. Furthermore, as illustrated in FIG. 9, the wall 33a comprises a protruding portion 33m used for connecting and positioning the wall 33a with respect to other members and components. The opening 33c is an example of a first opening.

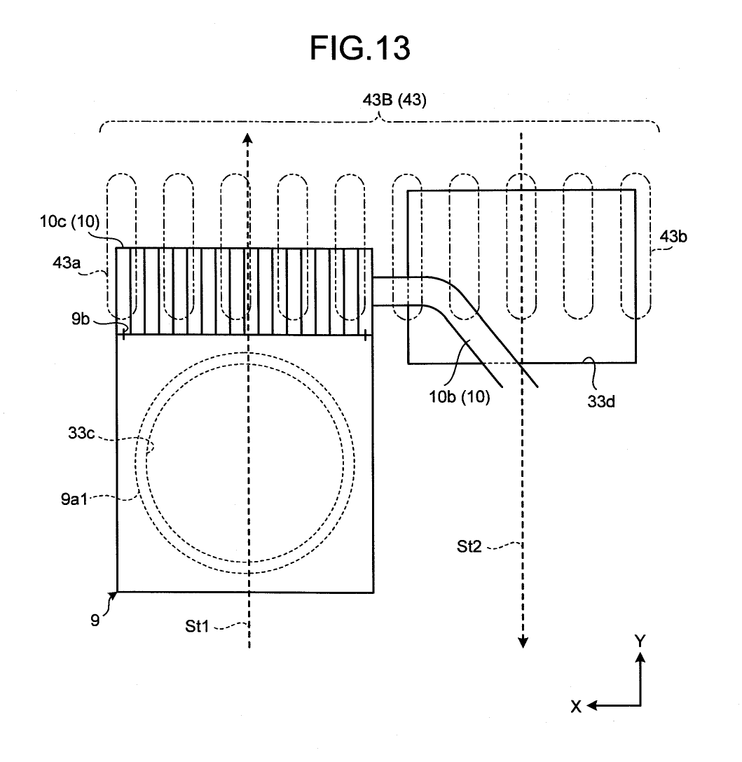

In the present embodiment, for example, an airstream St flows through the gap G1 between the wall 33a and the back surface 4b of the display device 4 as illustrated in FIG. 10. Specifically, as is clear from FIGS. 8 and 9, the fan 9 is arranged so as to cover the opening 33c provided to the wall 33a of the third housing member 33. As is illustrated in FIGS. 10 and 13, an air inlet 9a1 of the fan 9 is overlapped with the opening 33c. Therefore, in the present embodiment, for example, an air stream St1 illustrated in FIGS. 10 and 13 is generated. The air stream St1 enters the housing 3 through the vent 43A, flows through the gap G1 and the opening 33c, and enters the fan 9 from the air inlet 9a1 of the fan 9. The vent 43B faces an air outlet 9b of the fan 9. The heat dissipater 10c is arranged between the air outlet 9b and the vent 43B. Therefore, the air stream St1 flows from the air outlet 9b of the fan 9 through the heat dissipater 10c (e.g., through gaps between fins), and flows out of the housing 3 through the vent 43B. Such an air stream St1 can suppress a rise in temperature of (the back surface 4b of) the display device 4, for example. Furthermore, the air stream St1 can suppress a rise in temperature of the wall 33a of the third housing member 33, for example. As a result, is it possible to suppress a rise in temperature of the board 6 and the heating element 6a1 of the component 6a and the like (refer to FIGS. 8 and 9) mounted on the board 6. The air inlet 9a1 is an example of a second opening.

In the present embodiment, for example, the air outlet 9b of the fan 9 is arranged close to an end 43a side, that is, one end of the vent 43B extending along the end 3c of the housing 3 as illustrated in FIG. 13. In the present embodiment, for example, the end 43a is one end in the longitudinal direction, that is, the end on the left side illustrated in FIG. 13. In other words, the air outlet 9b of the fan 9 faces a part of the vent 43B (area on the left side in FIG. 13 in the present embodiment, for example). Therefore, the area on one side facing the air outlet 9b in the vent 43B (area on the left side in FIG. 13 in the present embodiment, for example) mainly functions as an outlet (air outlet). As a result, the other side of the vent 43B (area on the right side in FIG. 13 in the present embodiment, for example) mainly functions as an inlet (air inlet). In association with exhaustion of the air (air stream St1) from the area on one side of the vent 43B, pressure decreases in the housing 3. As a result, air (an air stream St2) is introduced from the area on the other side of the vent 43B.

In the present embodiment, for example, the opening 33d is arranged close to an end 43b side, that is, the other end of the vent 43B (the other end in the longitudinal direction, that is, the end on the right side in the present embodiment, for example) as illustrated in FIG. 13. The opening 33d faces the area on the end 43b side, that is, the other end of the vent 43B. Therefore, in the present embodiment, for example, the air stream St2 illustrated in FIGS. 10 and 13 is generated. The air stream St2 enters the housing 3 through the area on the other side of the vent 43B, and flows from the opening 33d through the gap G1. The temperature of the air stream St2 is lower than that of the inside of the housing 3 that houses the heating element 6a1. Therefore, air ventilation is promoted in the housing 3 including the gap G1, making it possible to suppress a rise in temperature of (the back surface 4b of) the display device 4, for example. Furthermore, the air stream St2 can suppress a rise in temperature of the wall 33a of the third housing member 33, for example. As a result, it is possible to suppress a rise in temperature of the board 6 and the heating element 6a1 of the component 6a and the like (refer to FIGS. 8 and 9) mounted on the board 6. The opening 33d is an example of a third opening.

In the present embodiment, for example, air streams St3 and St4 are generated in a gap G2 between the wall 33a of the third housing member 33 and the wall 3m of the second housing member 32 in association with the operation of the fan 9 in the housing 3 as illustrated in FIG. 10. The air stream St3 enters the housing 3 through the vent 43A, flows through the gap G2, and enters an air inlet 9a2 of the fan 9. The air inlet 9a2 is arranged on the opposite side (rear side) of the air inlet 9a1. The air stream St3 then flows from the air outlet 9b of the fan 9 through the heat dissipater 10c (e.g., through the gaps between the fins), and flows out of the housing 3 through the vent 43B. By contrast, the air stream St4 enters the housing 3 through the area on the other side of the vent 43B, and flows through the gap G2. The air streams St3 and St4 flowing through the gap G2 suppresses a rise in temperature of the heating element 6a1 of the component 6a and the like arranged in the gap G2. Furthermore, in the present embodiment, for example, the heat transfer module 10b connected to the heat dissipater 10c faces the area on the other side of the vent 43B as illustrated in FIG. 13. Therefore, the air stream St4 and the air stream St2 strike the heat transfer module 10b, thereby further suppressing a rise in temperature of the heat transfer module 10b. As a result, the cooling efficiency of the cooling device 10 can be further improved.

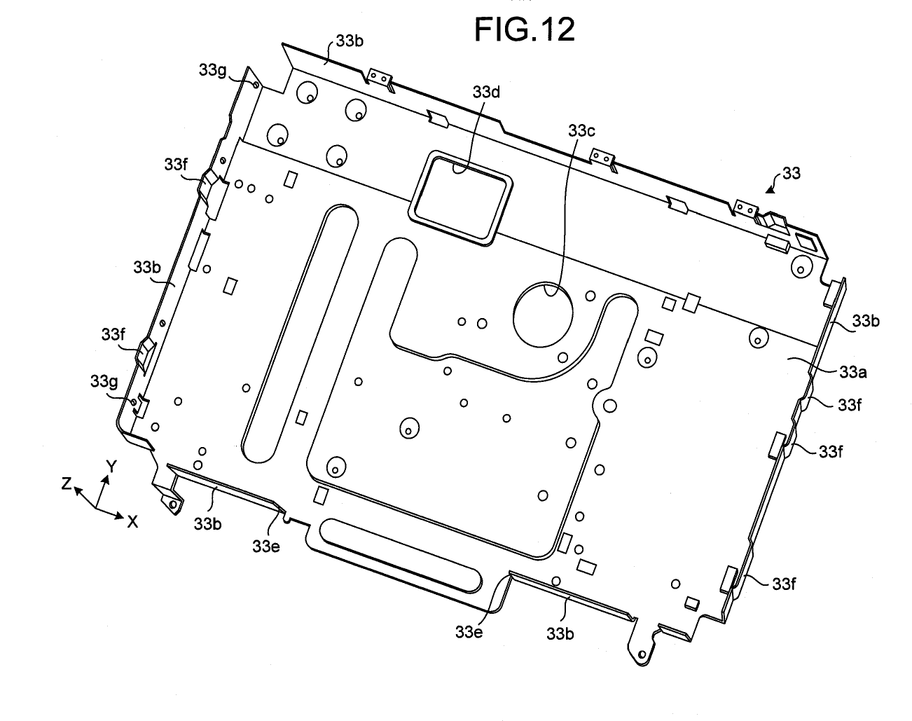

In the present embodiment, for example, an opening 33e is provided on the side opposite the vent 43B with respect to the opening 33c (lower side in the present embodiment, for example) in the third housing member 33 as illustrated in FIGS. 10 and 12. The opening 33e facilitates the flow of the air stream St1, for example. Furthermore, in the present embodiment, for example, the opening 33e is formed as a through-hole or a slit as illustrated in FIG. 12. In the present embodiment, for example, the opening 33e is formed as an area in which no wall 33b is partially provided, that is, a slit of the wall 33b. With such a configuration, the opening 33e can be formed in a simpler manner, for example. The opening 33e is an example of a fifth opening.

In the present embodiment, for example, the boards 6 and 7 are covered with the fourth housing member 34 as illustrated in FIGS. 8 and 9. Specifically, as illustrated in FIGS. 8 and 9, the fourth housing member 34 is formed in a plate shape as a whole. The fourth housing member 34 comprises a wall 34a and a wall 34b. The wall 34a is formed in a rectangular shape and a plate shape, and covers the back side (rear side or side opposite the display device 4) of the boards 6 and 7. A gap G3 is formed between the wall 34a and the boards 6 and 7. In other words, the wall 34a is arranged on the rear (rear side or back side) of the boards 6 and 7 with a space interposed therebetween. The wall 34b stands from the wall 34a at a periphery of the wall 34a. The wall 34b is an example of a side wall (a vertical wall, a standing wall, or a peripheral wall). The wall 34a has openings 34c. With the openings 34c, for example, it is possible to make the fourth housing member 34 lighter, and to improve the air ventilation in the housing 3. Furthermore, if the fourth housing member 34 is made of an electrically conductive material such as metal, the fourth housing member 34 can function as an electromagnetic shield. The fourth housing member 34 is connected to other housing members (e.g., the third housing member 33) by the fixture 42 such as a screw, for example. Furthermore, in the present embodiment, for example, a connector 11A (11) is fixed to the fourth housing member 34 as illustrated in FIGS. 8 and 9. With this configuration, for example, it is possible to fix the connector 11A (11) more tightly than the case where the connector 11A (11) is fixed to the boards 6 and 7. Furthermore, it is possible to arrange the connector 11A (11) at a position distant from the boards 6 and 7, for example.

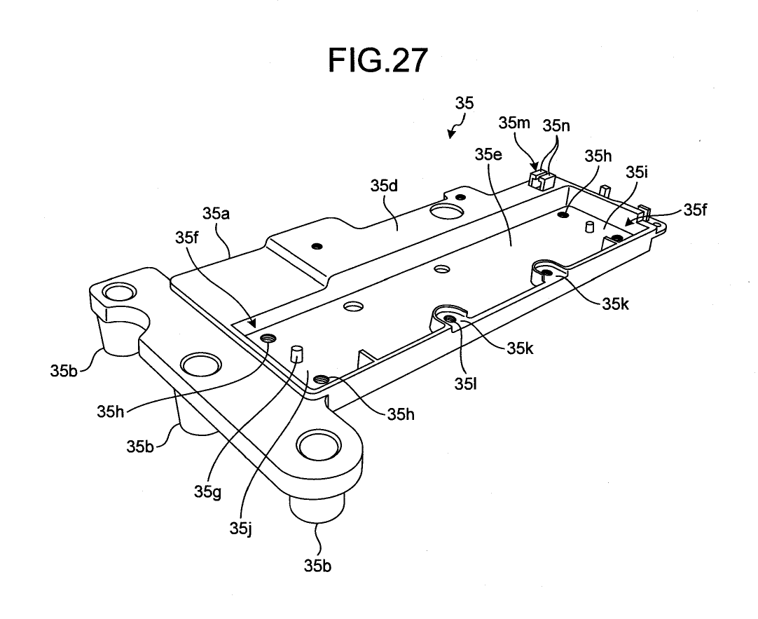

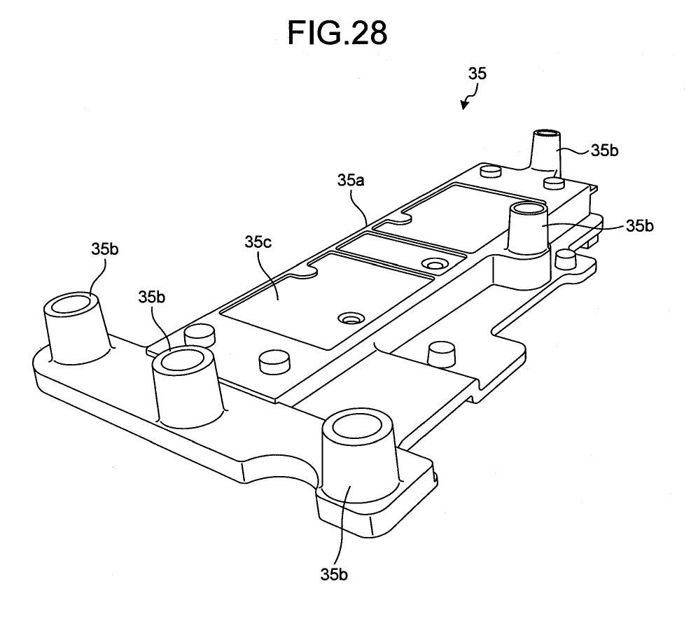

As is clear from FIGS. 8 and 9, the fifth housing member 35 is arranged on the rear side (side opposite the display device 4) at the center of the wall 33a of the third housing member 33 in the present embodiment, for example. The fifth housing member 35 is used as a fixing portion for the hinge 8. Furthermore, in the present embodiment, for example, the boards 6 and 7 are arranged on both sides with the fifth housing member 35 sandwiched therebetween. Therefore, it is possible to arrange the boards 6 and 7 efficiently by using spaces around the fifth housing member 35 while supporting the housing 3 more stably via the fifth housing member 35, for example. Furthermore, the fifth housing member 35, for example, comprises a base portion 35a in a plate shape and a protruding portion 35b protruding from the base portion 35a as illustrated in FIGS. 27 and 28. The protruding portion 35b protrudes from the base portion 35a toward the third housing member 33. Therefore, a gap (not illustrated) is formed between the base portion 35a and the wall 33a of the third housing member 33. As a result, it is possible to prevent the fifth housing member 35 from being an obstacle in the way of the air stream flowing toward the fan 9 in the housing 3, for example. The protruding portion 35b can be configured as a fixing part (a female screw) to which a fixture connecting the third housing member 33 and the fifth housing member 35 is fixed.

In the present embodiment, for example, the housing 3 houses components, such as a distributer 15 (a duplexer), a module 16 (e.g., an HDD), a module 17 (e.g., an optical disk drive (ODD)), and an antenna 18, as illustrated in FIGS. 8 and 9. These components are fixed to the first housing member 31, the third housing member 33, and the fifth housing member 35 by the fixture 42 such as a screw. Furthermore, the components and the boards 6 and 7 are electrically connected via the harness 19 (a line, a cable, or a wire).

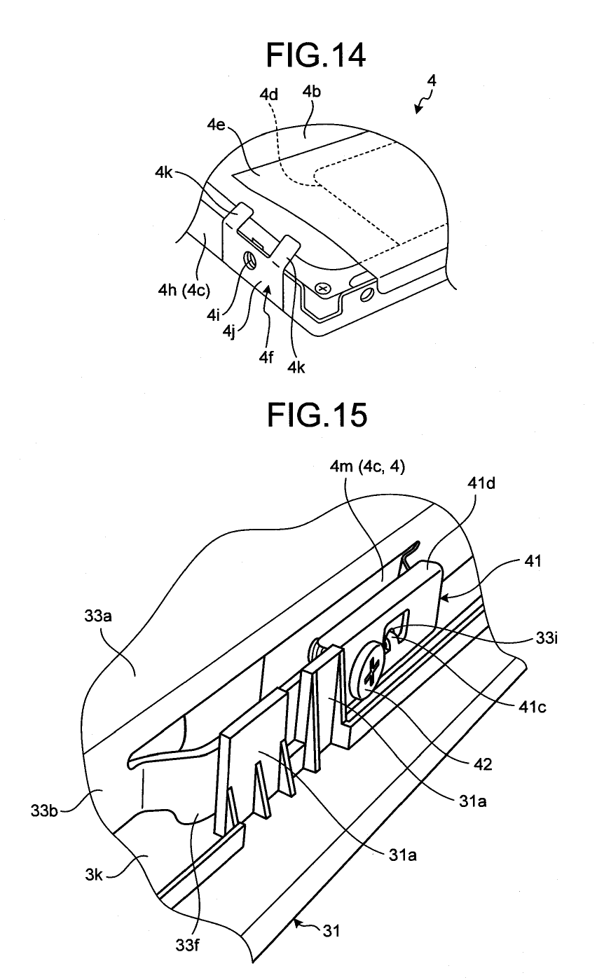

In the present embodiment, for example, a side surface 4c of one end 4h of the display device 4 comprises a fixing part 4i (e.g., a female screw hole) to which a fixture (not illustrated) such as a screw is fixed as illustrated in FIG. 14. In the present embodiment, for example, the end 4h is one end in the longitudinal direction or a short side (refer to FIG. 11). As illustrated in FIG. 12, the wall 33b of the third housing member 33 has an opening 33g into which the fixture is inserted. The opening 33g may be a through-hole or a cutout, and is a through-hole in the present embodiment, for example. The fixture is inserted into the opening 33g of the wall 33b, and is fixed to the fixing part 4i of the side surface 4c. As a result, the display device 4 and the third housing member 33 are connected. In the present embodiment, for example, the position of the opening 33g of the wall 33b and the position of the fixing part 4i of the side surface 4c can specify the size of the gap G1 (refer to FIG. 10) between the back surface 4b of the display device 4 and the wall 33a of the third housing member 33. A guide member 4f is attached to the side surface 4c. The guide member 4f causes (guides) the third housing member 33 and the display device 4 to come close to each other when the third housing member 33 and the display device 4 are integrated. The guide member 4f is made of a relatively soft material (e.g., a synthetic resin material), for example. The guide member 4f comprises a base portion 4j fixed to the side surface 4c and a protruding portion 4k protruding rearward in a state bent toward the center of the display device 4 from the base portion 4j.

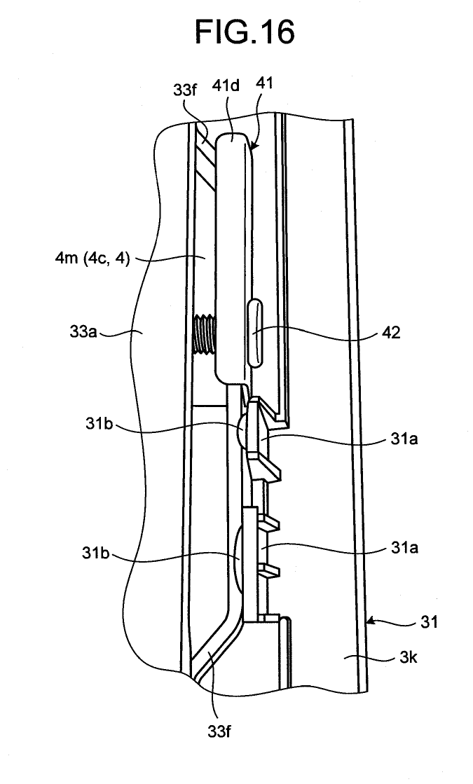

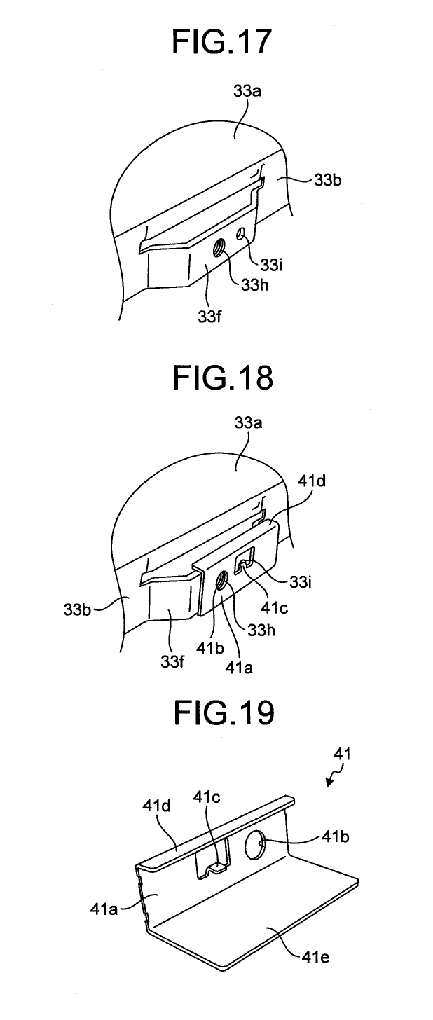

In the present embodiment, for example, the fixing part 4i is not provided to an end 4m (refer to FIGS. 15 and 16) on the side opposite the end 4h to which the fixing part of the display device 4 is provided. Therefore, in the present embodiment, for example, a clip 41 (a clamp, a bracket, an attachment component, or an engaging component) is used for connecting the end 4m and the third housing member 33. Specifically, as illustrated in FIG. 17, the wall 33b of the third housing member 33 comprises an engaging part 33f protruding out of the housing 3 from the wall 33b. In the present embodiment, for example, the engaging part 33f is formed by partially cutting and raising the wall 33b. The engaging part 33f comprises a fixing part 33h (e.g., a female screw hole) and a positioner 33i (which may be an opening, and is a through-hole in the present embodiment, for example). Furthermore, in the present embodiment, for example, the clip 41 functions as a hook bent in a U shape as illustrated in FIG. 19. A wall 41a serving as the bottom portion of the U has an opening 41b into which the fixture 42 such as a screw is inserted and a positioner 41c corresponding to the positioner 33i. The opening 41b may be a through-hole or a cutout, and is a through-hole in the present embodiment, for example. The positioner 41c may be a projection or a claw, and is formed by being cut and raised in the present embodiment, for example. A wall 41d protrudes from an end on one side (rear side) of the wall 41a, and a wall 41e protrudes from an end on the other side (front side) of the wall 41a. The clip 41 engages with the third housing member 33 in a state illustrated in FIG. 18. In other words, the projection serving as the positioner 41c of the clip 41 is inserted into the opening serving as the positioner 33i of the engaging part 33f. The fixture 42 (refer to FIG. 15) inserted into the opening 41b of the clip 41 is fixed to the fixing part 33h of the engaging part 33f. The wall 41d covers the edge on the rear side of the engaging part 33f, and the wall 41e covers the periphery of the display screen 4a of the display device 4 from the front. In other words, the clip 41 attached to the third housing member 33 hooks the periphery of the display screen 4a of the display device 4 on the end 4m side of the display device 4. As a result, it is possible to connect the display device 4 and the third housing member 33.

In the present embodiment, for example, the periphery of the wall 3k of the first housing member 31 comprises an engaging part 31a as illustrated in FIGS. 15 and 16. The engaging part 31a engages with the engaging part 33f of the third housing member 33. Specifically, the engaging part 31a protrudes toward the inside (rear side or back side) of the housing 3 along the engaging part 33f at a position adjacent to the clip 41 from the periphery of the wall 3k. As illustrated in FIG. 16, a claw 31b is provided to a tip of the engaging part 31a. The claw 31b and the engaging part 33f engage with each other, thereby connecting the first housing member 31 and the third housing member 33.

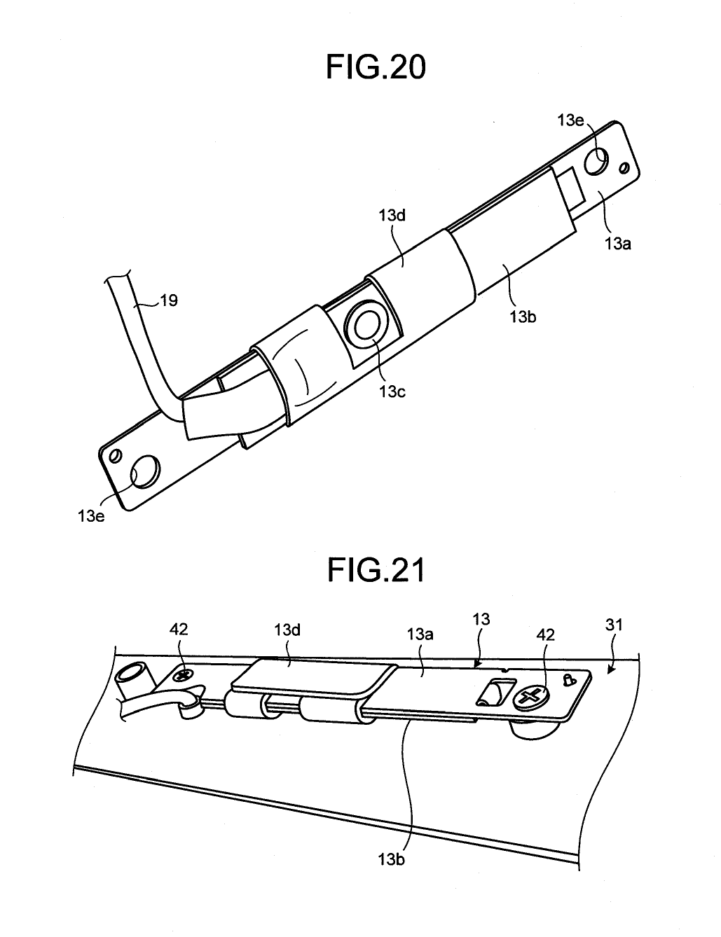

In the present embodiment, for example, the camera module 13 is connected to the first housing member 31 by the fixture 42 such as a screw as illustrated in FIG. 21. In the present embodiment, for example, the camera module 13 comprises a base 13a, a board 13b (circuit board), and a camera 13c as illustrated in FIG. 20. The base 13a is formed in a strip shape (rectangle shape) and a plate shape extending along the end 3c of the housing 3. The base 13a is made of a material having relatively high rigidity, that is, a metal material such as stainless steel, for example. The board 13b is formed in a strip shape (rectangle shape) and a plate shape extending along the end 3c of the housing 3. However, the board 13b is shorter than the base 13a. In other words, the base 13a projects from both sides of the board 13b in the longitudinal direction. The camera 13c is fixed to the board 13b. The board 13b is fixed to the base 13a by a fixing member such as a tape 13d. The portion of the base 13a projecting from the board 13b has an opening 13e into which the fixture 42 is inserted. The opening 13e may be a through-hole or a cutout, and is a through-hole in the present embodiment, for example. With such a configuration, for example, it is possible to provide the camera module 13 in a relatively simple manner. Furthermore, attachment of the board 13b to the base 13a can increase the rigidity of the camera module 13, for example.

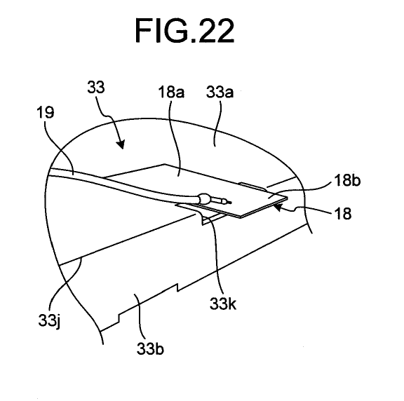

In the present embodiment, for example, an opening 33k is provided to an end 33j that is a boundary between the wall 33a and the wall 33b of the third housing member 33 as illustrated in FIG. 22. The opening 33k may be a through-hole or a cutout, and is a through-hole in the present embodiment, for example. The antenna 18 is fixed to the portion in which the opening 33k is provided in the third housing member 33. The antenna 18 is formed in a rectangular shape (an oblong shape in the present embodiment, for example) viewed from the front or the back with respect to the display screen 4a, and comprises a fixing part 18a and a communication module 18b. It is preferable that the communication module 18b be distant from an electrically conductive material such as metal. In the present embodiment, for example, the opening 33k is provided, whereby an edge of the third housing member 33 retreats toward the center of the wall 33a. As a result, it is possible to reduce a protruding amount of the antenna 18 from the end 33j of the third housing member 33. In the present embodiment, for example, the antenna 18 is provided in plurality (two antennas are provided in the present embodiment, for example) as illustrated in FIGS. 8 and 9. The antennas 18 may be the antennas 18 in different communication systems, may be used for transmission and reception, or may be used for space diversity.

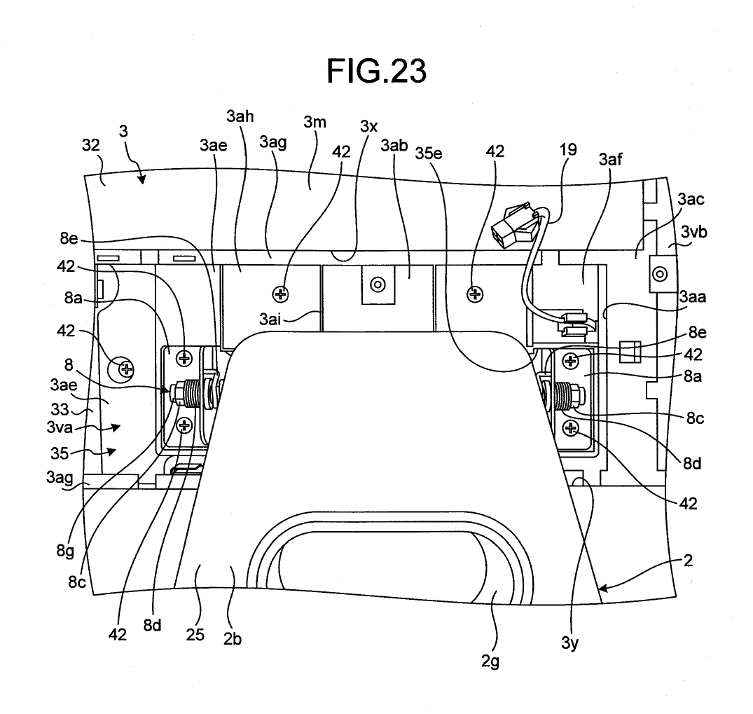

An example of a coupling portion of the housing 3 and the support 2 will now be described. As illustrated in FIGS. 23 to 25, the support 2 is coupled to the fifth housing member 35 of the housing 3 via the hinge 8. The hinge 8 is an example of a coupling part that couples the support 2 and the fifth housing member 35. FIGS. 23 to 25 illustrates a state in which covers 3wa and 3wb (refer to FIG. 2) that cover openings 3va and 3vb provided to the wall 3m, respectively, are removed.

As illustrated in FIGS. 23, 25, and 29, the hinge 8 comprises a plurality of (specifically, two) attachments 8a, a shaft 8b, fasteners 8c, resistant members 8d, biasing members 8e, and engaging parts 8f.

The shaft 8b extends in the horizontal direction, and is connected to two attachments 8a. The shaft 8b is an example of a connection. The shaft 8b is fixed to the support 2 by the fixture 42 (FIG. 29).

The attachments 8a are attached to the right and left ends of the shaft 8b in a rotatable manner. As illustrated in FIG. 29, each of the attachments 8a comprises a wall 8g inserted into the shaft 8b and a wall 8h bent from the wall 8g and fixed to the fifth housing member 35. The wall 8h has a positioner 8i and holes 8j. The positioner 8i is a hole, for example. Two holes 8j are arranged in an aligned manner in the vertical direction. The positioner 8i is arranged between the two holes 8j.

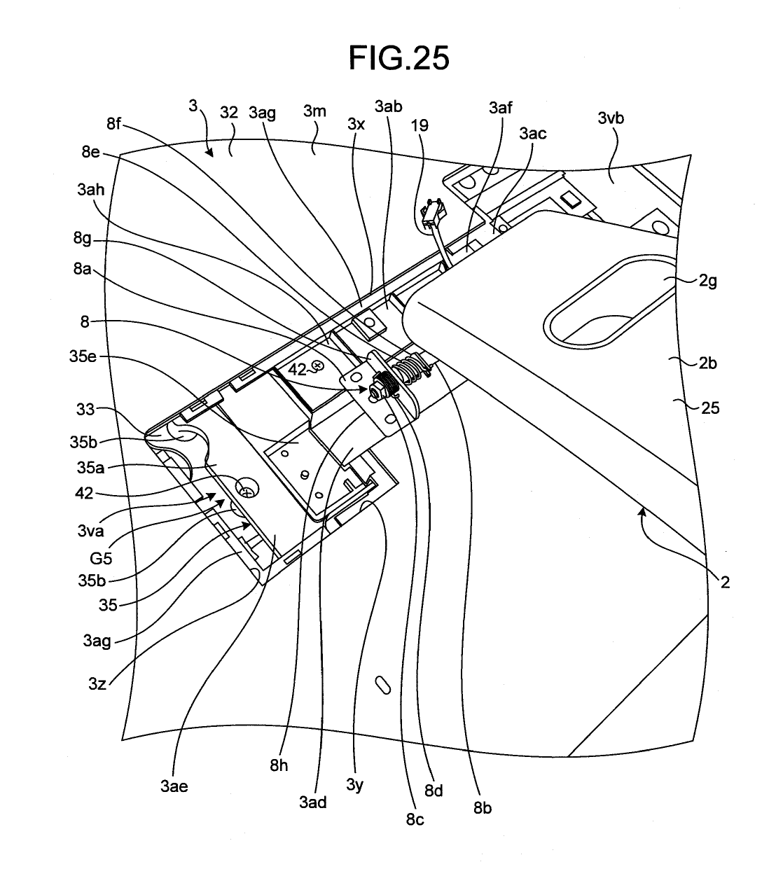

As illustrated in FIG. 25, the resistant member 8d is arranged on the outside of the wall 8g (end side of the shaft 8b in the axis direction). The resistant member 8d is prevented from coming off by the fastener 8c. The resistant member 8d is a coil spring (compressed spring), for example. The resistant member 8d functions as rotational resistance of the attachment 8a to the shaft 8b. The rotational resistance caused by the resistant member 8d maintains the angle of the housing 3. By contrast, the biasing member 8e and the engaging part 8f are arranged on the inside of the wall 8g (center side of the shaft 8b in the axis direction). The engaging part 8f is a plate-shaped member, for example. The engaging part 8f is fixed to the shaft 8b. The biasing member 8e is a twisted coil spring, for example, and is coupled to the engaging part 8f and the wall 8g. The biasing module 8e biases the attachment 8a in a direction in which the housing 3 tilts backward (anti-clockwise direction in FIG. 3). With this configuration, an operator can tilt the housing 3 backward with relatively small strength.

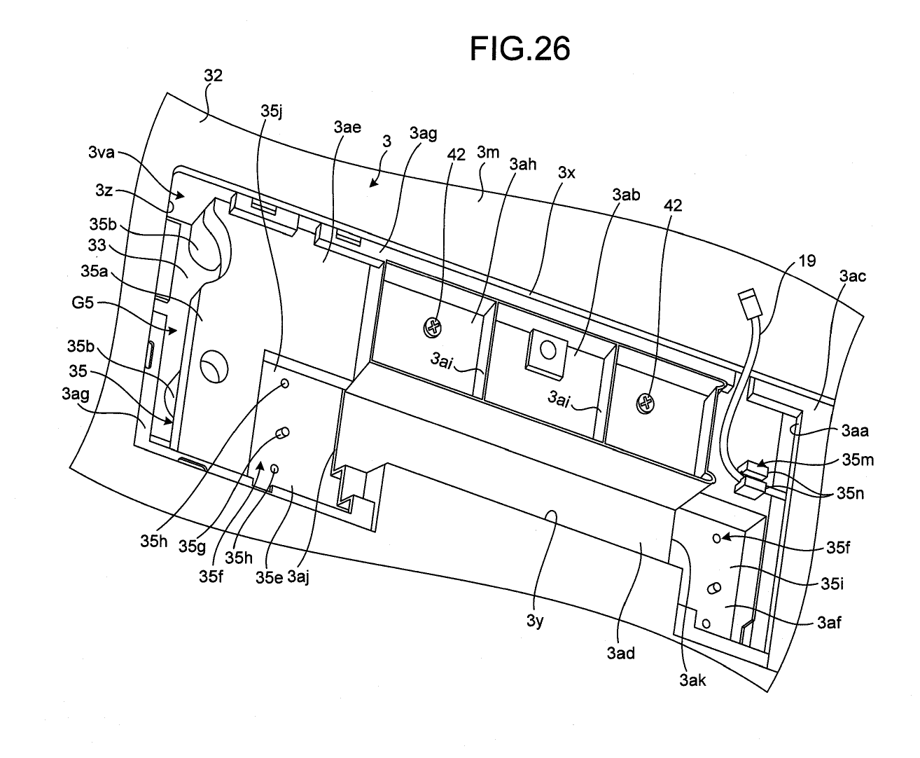

As illustrated in FIG. 26 and other drawings, the fifth housing member 35 is fixed to the third housing member 33 so as to face the opening 3va of the wall 3m of the housing 3. The fifth housing member 35 is arranged on the side opposite the display device 4 with respect to the third housing member 33. The fifth housing member 35 is arranged on the back surface 4b side of the display device 4.

As illustrated in FIGS. 27 and 28, the fifth housing member 35 comprises the base portion 35a and the convex portion 35b provided in plurality.

The base portion 35a is formed in a plate shape, for example. A recess 35e recessed toward the display device 4 is provided to a rear surface 35d (a back surface, a surface, or a section) of the base portion 35a. The recess 35e comprises a plurality of (specifically, two) fixing parts 35f. The fixing parts 35f are provided to right and left ends 35i and 35j of the recess 35e. The attachments 8a of the hinge 8 are fixed to the fixing parts 35f. In detail, the fixing part 35f comprises a positioner 35g and fixing parts 35h. The positioner 35g is a projection (a convex portion or a pin), for example, and is inserted into the positioner 8i of the hinge 8. Each of the fixing parts 35h is a screw hole, for example. Two fixing parts 35h are arranged in an aligned manner in the vertical direction. The positioner 35g is arranged between the two fixing parts 35h. The fixture 42 inserted into the hole 8j of the hinge 8 is fixed to the fixing part 35h.

Furthermore, the base portion 35a comprises a fixing part 35k to which the module 16 is fixed. In detail, the fixing part 35k is provided in plurality (specifically, two fixing parts) along the horizontal direction on the lower edge of the recess 35e. The fixing part 35k has a screw hole 35l. The fixture 42 passing through the module 16 is connected to the screw hole 35l, whereby the module 16 is fixed to the fixing part 35k.

Furthermore, the fifth housing member 35 comprises a holder 35m that holds the harness 19 as illustrated in FIG. 27. The holder 35m sandwiches and holds the harness 19 by two holding claws 35n.

As illustrated in FIG. 28, the convex portion 35b protrudes toward the display device 4 from a front surface 35c (a front face, a surface, or a section) of the base portion 35a. The convex portion 35b is formed in a cylindrical shape, for example. The inside of the convex portion 35b is formed in a two-stage structure with two different inside diameters, thereby forming a step. The fixture 42 (FIG. 25) engages with the step, whereby the fifth housing member 35 is fixed to the third housing member 33. As a result, a gap G5 (refer to FIG. 25) is formed between the base portion 35a of the fifth housing member 35 fixed to the third housing member 33 and the third housing member 33. Airflows through the gap G5 by an operation of the fan 9.

As illustrated in FIGS. 23 to 26, the wall 3m of the second housing member 32 has the opening 3va through which the fifth housing member 35 is exposed. The opening 3va is arranged side by side with another opening 3vb with a partition 3ac interposed therebetween.

The opening 3va houses at least a part of the hinge 8, and exposes at least a part of the fifth housing member 35. In the present embodiment, the opening 3va houses at least the shaft 8b of the hinge 8, and exposes at least the right and left ends of the base portion 35a of the fifth housing member 35. As illustrated in FIG. 26, the opening 3va is formed in a nearly rectangular shape viewed from the back, and comprises four edges, i.e., a first edge 3x (upper edge), a second edge 3y (lower edge), a third edge 3z (one edge), and a fourth edge 3aa (the other edge). The first edge 3x and the second edge 3y are separated from and opposite to each other. The third edge 3z and the fourth edge 3aa are separated from and opposite to each other, and connect the first edge 3x and the second edge 3y. The fourth edge 3aa is provided to the partition 3ac. Furthermore, the edge of the opening 3va comprises a flange 3ag that supports the cover 3wa.

An extending portion (a wall portion, a wall, or a section) 3ab is provided to the opening 3va. The extending portion 3ab is arranged in a manner extending between the edges of the opening 3va, that is, between the first edge 3x and the second edge 3y. The extending portion 3ab is an example of a portion of the second housing member 32. The extending portion 3ab is arranged between the support 2 and the fifth housing member 35. The extending portion 3ab, which is a part of the housing 3, extends inside of the opening 3va, and is covered with the support 2.

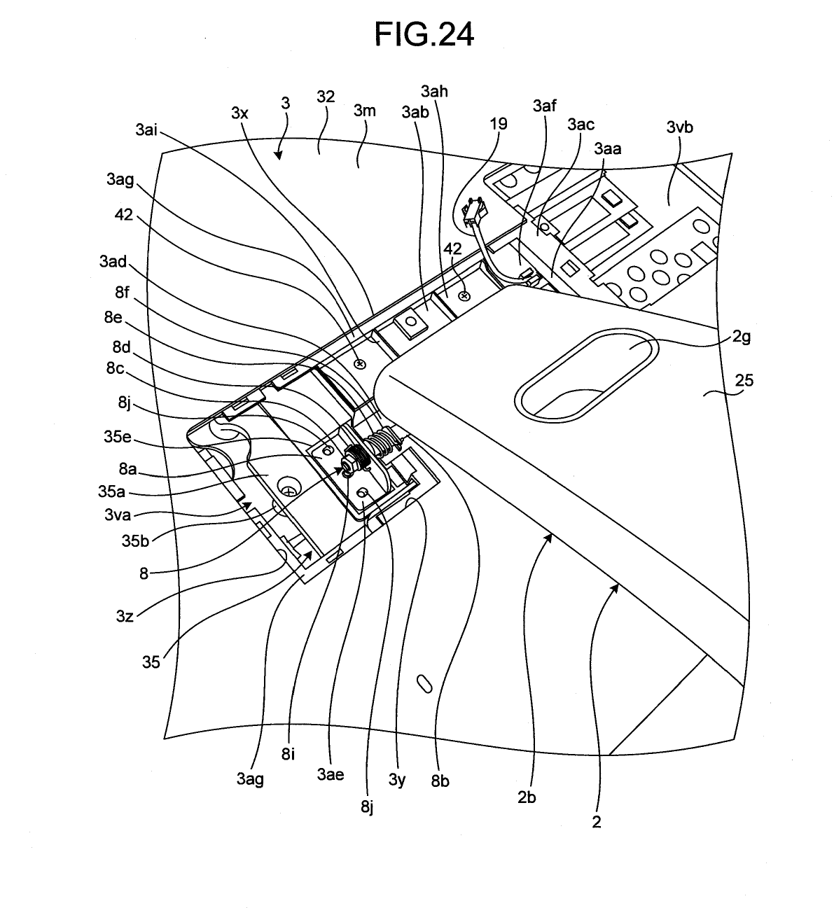

The extending portion 3ab comprises a recess 3ad. The recess 3ad extends in the horizontal direction. The recess 3ad is recessed toward the display device 4. The recess 3ad houses at least a part of the hinge 8 (FIG. 24). Specifically, the recess 3ad houses the shaft 8b of the hinge 8. The recess 3ad is arranged over the recess 35e of the fifth housing member 35. At least a part of the recess 3ad is housed in the recess 35e. The recess 3ad may be brought into contact with the recess 35e, or may be separated from the recess 35e.

The extending portion 3ab comprises a fixing part 3ah. The fixing part 3ah is arranged on the upper side of the recess 3ad. The fixing part 3ah is connected (fixed) to the fifth housing member 35 by the fixture 42 (screw). The number of fixtures 42 that connect (fix) the fixing part 3ah to the fifth housing member 35 is two in the present embodiment, for example. Furthermore, ribs 3ai are arranged between the two fixtures 42 in the fixing part 3ah.

As illustrated in FIG. 26, the opening 3va is divided into three portions of an opening 3ae, the recess 3ad (opening), and an opening 3af by the extending portion 3ab. The recess 3ad communicates with the opening 3ae on one end, and communicates with the opening 3af on the other end. The opening 3ae is an opening specified by an edge 3aj of the extending portion 3ab, an edge 3z of the opening 3va, and the like. The opening 3af is an opening specified by an edge 3ak of the extending potion, an edge 3aa of the opening 3va, and the like. At least one of the hinge 8 and the fifth housing member 35 is passed through the openings 3ae and 3af. In the present embodiment, for example, the shaft 8b of the hinge 8 is passed through the openings 3ae and 3af as illustrated in FIG. 23. The openings 3ae and 3af expose the attachment 8a of the hinge 8. If the hinge 8 is removed from the fifth housing member 35, the openings 3ae and 3af expose the fixing part 35f of the fifth housing member 35. The extending portion 3ab is arranged between the openings 3ae and 3af in a manner sandwiched between the support 2 and the fifth housing member 35.

The support 2 will now be described. As illustrated in FIG. 29, the support 2 comprises a grounding portion 2a (first section) and a standing portion 2b (second section). The support 2 is an example of a stand. The support 2 supports the housing 3 on the rear surface 4b side of the display device 4.

As illustrated in FIG. 29 to FIG. 31, the grounding portion 2a comprises a first supporting member 21 (a cover or an under cover), a second supporting member 22 (a cover or an upper cover), and a third supporting member 23 (a bottom wall, a wall, an internal component, a reinforcing component, a support, a structure member, a metal component, a frame, a structure member, or a base). The first supporting member 21 covers at least a part of the third supporting member 23 from the outside of the third supporting member 23.

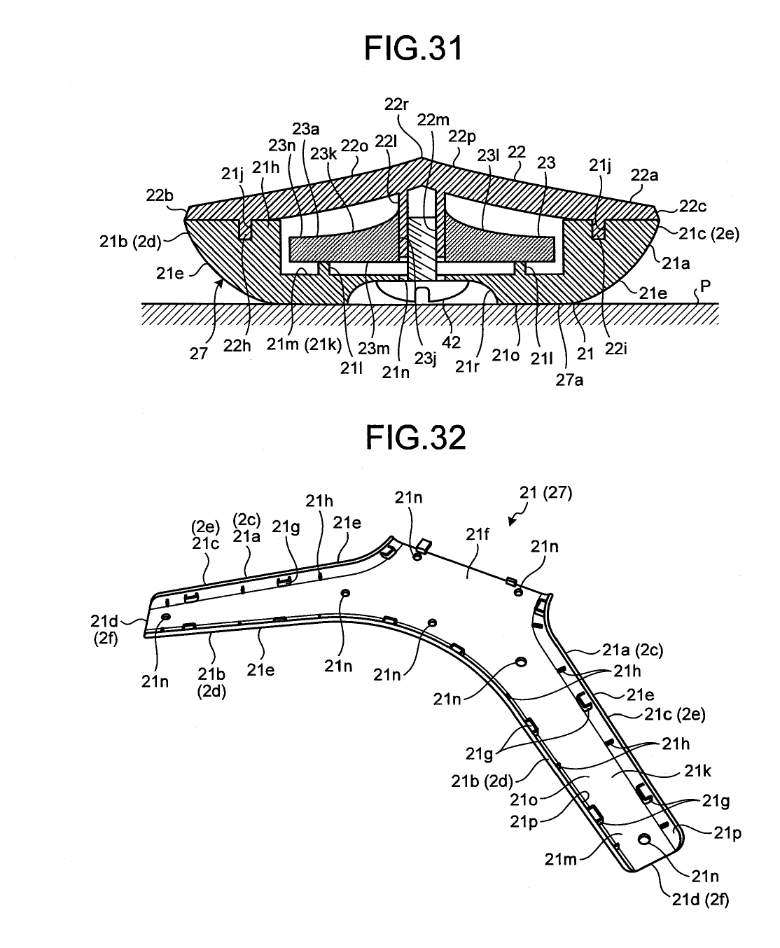

The first supporting member 21 and the second supporting member 22 constitute a covering member 27 (a housing section or a case) that covers (houses) the third supporting member 23. The covering member 27 covers a bottom surface 23m (FIG. 31) of the third supporting member 23. As illustrated in FIG. 31, the covering member 27 is made of resin, for example, and the third supporting member 23 is made of metal, for example. In other words, the covering member 27 has lower rigidity than that of the third supporting member 23. The covering member 27 comprises an area 27a (a bottom wall, a wall, an area, a section, a rubber leg, or a leg (FIG. 31)). When the covering member 27 is placed on an external placement surface P (horizontal surface), the area 27a covers at least a part of the third supporting member 23 on the external placement surface P side, and faces the external placement surface P. Furthermore, the covering member 27 comprises an inclining portion 21e (a projecting portion, a bottom wall, an edge, or a designed portion) inclining in a direction away from the external placement surface P when the grounding portion 2a is placed on the external placement surface P. The inclining portion 21e maybe curved, for example. Alternatively, the inclining portion 21e may incline with respect to the external placement surface P at a constant angle (e.g., 45 degrees), for example.

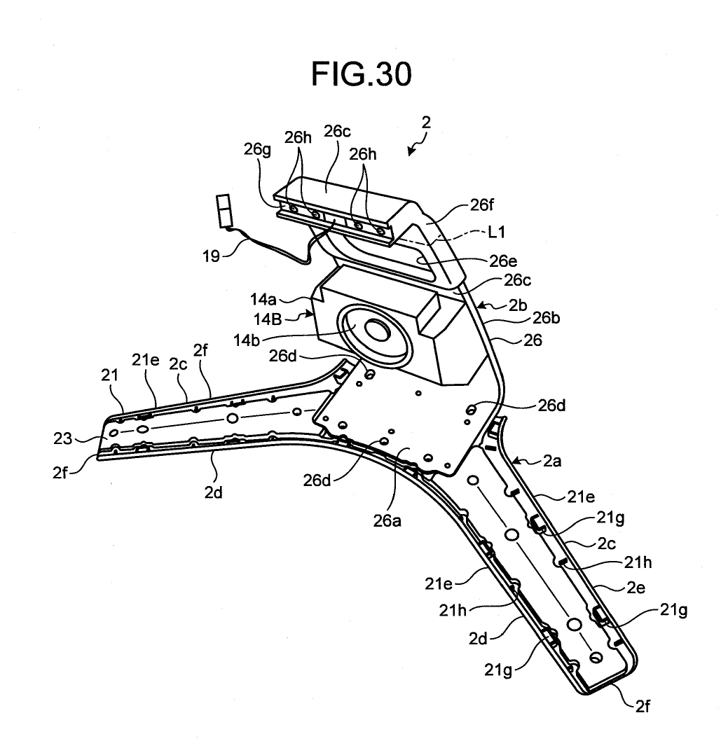

By contrast, the standing portion 2b comprises a fourth supporting member 24 (a cover or a front cover), a fifth supporting member 25 (a cover or a rear cover), and a sixth supporting member 26 (a frame, a structure member, or a base) as illustrated in FIGS. 29 and 30. The standing portion 2b is connected to the housing 3 on the rear surface 4b side of the display device 4, and connects the housing 3 and the grounding portion 2a.

Components in the grounding portion 2a and the standing portion 2b will now be described in detail.

As illustrated in FIG. 29, the covering member 27 comprises an elongating portion 2c that elongates along the external placement surface P when the covering member 27 is placed on the external placement surface P. Two elongating portions 2c are provided, for example. The elongating portions 2c are connected to each other by a connecting portion 2j. The inclining portions 21e are provided to ends 2d and 2e of the elongating portion 2c in the lateral direction. In other words, the inclining portion 21e is provided to at least the front face (front surface) side of the display device 4a in the grounding portion 2a. The covering member 27 comprises the first supporting member 21 and the second supporting member 22, and covers the third supporting member 23. When the covering member 27 is placed on the external placement surface P, the first supporting member 21 is positioned on the external placement surface P side of the third supporting member 23. By contrast, the second supporting member 22 is positioned on the side opposite the first supporting member 21. The first supporting member 21 and the second supporting member 22 are connected to each other by the fixture 42 (FIG. 31).

As illustrated in FIG. 32, the first supporting member 21 comprises a pair of elongating portions 21a. The elongating portions 21a are connected to each other by a connecting portion 21f. The elongating portion 21a comprises ends 21b and 21c in the lateral direction and an end 21d (tip) in the longitudinal direction. The first supporting member 21 comprises a bottom portion 21o (a bottom wall, a wall portion, a wall, or a section), and the inclining portion 21e is provided to the front edge and the rear edge of the bottom portion 21o. The inclining portion 21e stands from the bottom portion 21o. The inclining portion 21e projects while extending away from the external placement surface P when the grounding portion 2a is placed on the external placement surface P. The inclining portion 21e may extend to reach the second supporting member 22. A concave potion 21k is provided to the second supporting member 22 side of the first supporting member 21. The recess 21k houses the third supporting member 23.

As illustrated in FIG. 31, the recess 21k comprises a rib 21l. Furthermore, a hole 21n is provided to a bottom portion 21m (a bottom, a section, a wall, or a wall portion) of the recess 21k that constitutes the bottom portion 21o. The hole 21n is an example of a first opening. The hole 21n is bored in a recess 21r provided to the bottom portion 21o. The recess 21r houses the fixture 42.

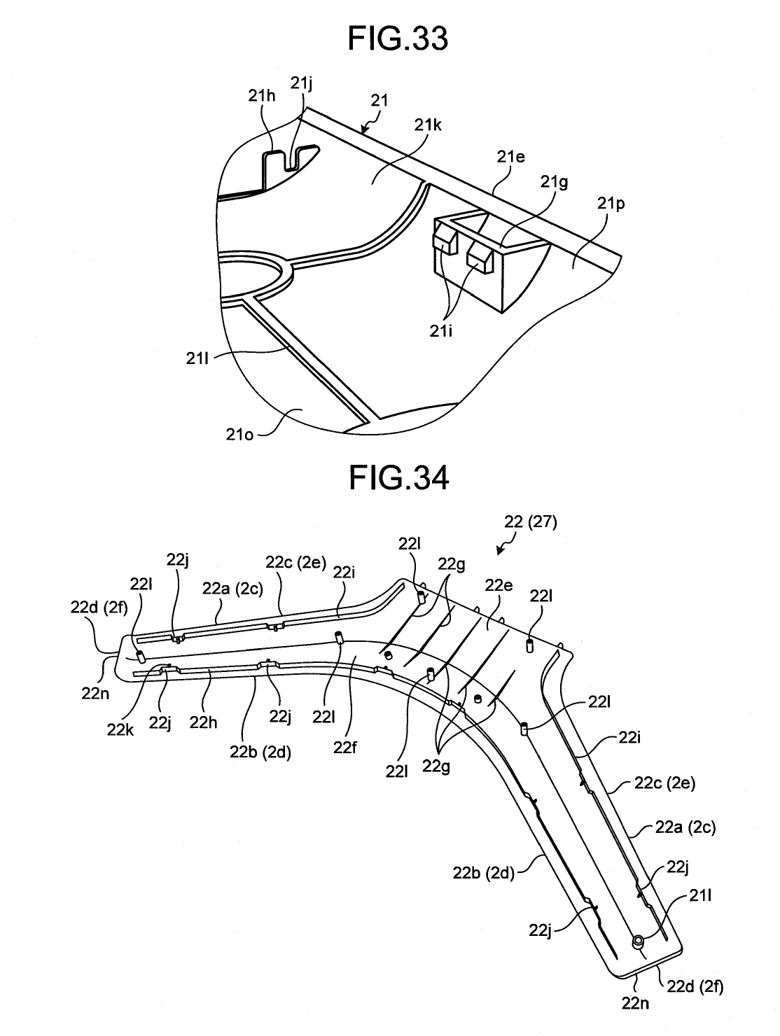

Furthermore, an inner surface 21p (a back surface, a surface, or a section) of the inclining portion 21e comprises a plurality of engaging parts 21g and 21h. The engaging parts 21g and 21h are arranged with a space interposed therebetween along the ends 21b and 21c of the elongating portion 21a. As illustrated in FIG. 33, the engaging part 21g comprises a pair of claws 21i. The engaging part 21h has a groove 21j.

As illustrated in FIG. 34, the second supporting member 22 comprises a pair of elongating portions 22a. The elongating portions 22a are connected to each other by a connecting portion 22e. The elongating portion 22a comprises ends 22b and 22c in the lateral direction and an end 22d (tip) in the longitudinal direction. The second supporting member 22 covers the recess 21k of the first supporting member 21.

An inner surface 22f (a back surface, a lower surface, or a section) of the second supporting member 22 comprises ribs 22g, 22h, and 22i (reinforcing parts, walls, or sections). The rib 22g is provided in plurality to the connecting portion 22e. The rib 22h is provided along the end 22b of the elongating portion 22a, whereas the rib 22i is provided along the end 22c of the elongating portion 22a. The third supporting member 23 is housed between the ribs 22h and 22i. The ribs 22h and 22i engage with the engaging part 21j (FIG. 31) of the first supporting member 21. The ribs 22h and 22i comprise a plurality of engaging parts 22j. The engaging parts 22j are arranged with a space interposed therebetween along the longitudinal direction of the ribs 22h and 22i. As illustrated in FIG. 36, the engaging part 22j protrudes toward the third supporting member 23. The engaging part 22j comprises a rib 22k and a hole 22q. The pair of claws 21i of the engaging part 21g in the first supporting member 21 engage with the hole 22q.

As illustrated in FIGS. 34 and 36, the inner surface 22f of the second supporting member 22 comprises an engaging part 22l. The engaging part 22l is a boss (a projection or a convex portion), for example. The engaging part has a screw hole 22m. The engaging part 22l is an example of a first engaging part. The first engaging part may be provided to the first supporting member 21. In other words, the first engaging part may be provided to at least one of the first supporting member 21 and the second supporting member 22.

The end 22d in the longitudinal direction of the elongating portion 22a of the second supporting member 22 comprises a second inclining portion 22n. The second inclining portion 22n projects while extending toward the external placement surface P when the grounding portion 2a is placed on the external placement surface P (FIG. 29).

Furthermore, as illustrated in FIG. 31, third inclining surfaces 22o and 22p are provided to the upper portion of the elongating portion 22a of the second supporting member 22. The third inclining surfaces 22o and 22p protrude while extending toward a center portion 22r in the lateral direction from the ends 22b and 22c in the lateral direction of the elongating portion 22a. With this configuration, the second supporting member 22 is formed in a mountain shape, whereby it is possible to cause the covering member 27 to appear relatively thin. Furthermore, in the elongating portion 22a, the center portion 22r in the lateral direction of the elongating portion 22a is thicker (having a larger thickness) than the ends 22b and 22c in the lateral direction of the elongating portion 22a. The elongating portion 22a is supported by the first supporting member 21.

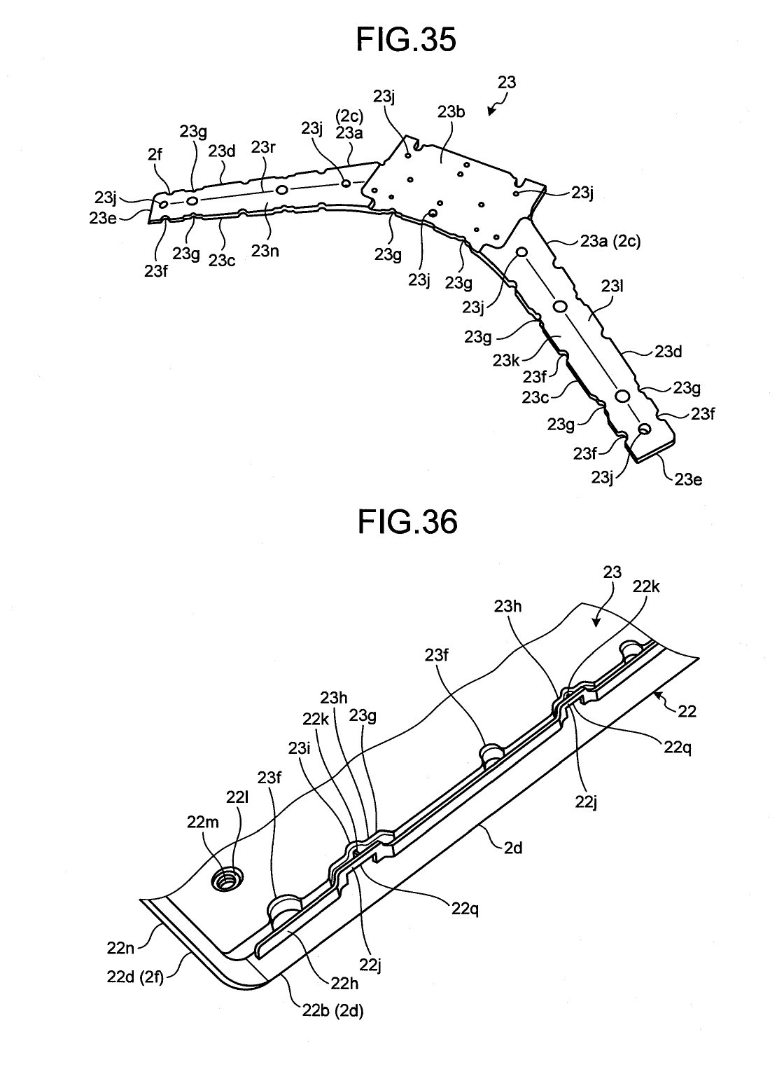

As illustrated in FIG. 35, the third supporting member 23 comprises a pair of elongating portions 23a. The elongating portions 23a are connected to each other by a connecting portion 23b. The connecting portion 23b is formed in a rectangular shape. The elongating portion 23a comprises ends 23c and 23d in the lateral direction and an end 23e (tip) in the longitudinal direction. The ends 23c and 23d of the elongating portion 23a comprise a plurality of recesses 23f and 23g. The recess 23f and the recess 23g are arranged alternately in the longitudinal direction of the elongating portion 23a. The recess 23f makes room for (houses) the engaging part 21h of the first supporting member 21. The recess 23g comprises a first recess 23h and a second recess 23i. The recess 23g makes room for (houses) the engaging part 22j of the second supporting member 22. The recess 23g is also provided to the connecting portion 23b.

Furthermore, fourth inclining surfaces 23k and 23l are provided to an upper surface 23n of the elongating portion 23a. The fourth inclining surfaces 23k and 23l protrude while extending toward a center portion 23r in the lateral direction from the ends 23c and 23d in the lateral direction of the elongating portion 23a. By contrast, the lower surface 23m of the elongating portion 23a is formed substantially flat.

The third supporting member 23 has a plurality of holes 23j. The holes 23j are provided to the pair of elongating portions 23a and the connecting portion 23b. As illustrated in FIG. 31, the engaging part 22l of the second supporting member 22 is inserted into the holes 23j. Furthermore, the fixture 42 inserted into the hole 21n of the first supporting member 21 is connected to the engaging part 22l of the second supporting member 22. In this state, the fixture 42 is inserted into the holes 23j. The fixture 42 used herein is a fixture that is inserted into the hole 21n provided to the first supporting member 21, and that is connected to the second supporting member 22.

As illustrated in FIG. 29, a front surface 2m (a front face, a wall, a wall portion, or a section) of the standing portion 2b comprises a first surface 2h and a second surface 2i extending downward from the first surface 2h. The second surface 2i is an inclining surface extending rearward as the surface extends downward. The standing portion 2b has an opening 2g of the standing portion. The opening 2g is provided to the first surface 2h, and penetrates the standing portion 2b from the front surface 2m and a rear surface 2n. A harness, a cable, and the like can be inserted into the opening 2g.

The fourth supporting member 24 contains the front surface 2m (the first surface 2h and the second surface 2i) of the standing portion 2b. An upper portion of a front wall 24a of the fourth supporting member 24 has an opening 24b to which a part of the sixth supporting member 26 is inserted. The fourth supporting member 24 is made of resin, for example. By contrast, the fifth supporting member 25 contains the rear surface 2n of the standing portion 2b. The fifth supporting member 25 is made of resin, for example. The fourth supporting member 24 and the fifth supporting member 25 constitute a second covering member 28 that covers (houses) the sixth supporting member 26.

As illustrated in FIG. 30, the sixth supporting member 26 comprises a base portion 26a, a wall 26b, and an attachment 26c. The sixth supporting member 26 is made of metal, for example. In the sixth supporting member 26, an area 26f positioned upper than a dashed-dotted line L1 in FIG. 30 is painted with nearly the same color as that for the fourth supporting member 24.

The base portion 26a is placed on the connecting portion 23b of the third supporting member 23. The base portion 26a has a hole 26d. The base portion 26a is sandwiched between the first supporting member 21 and the second supporting member 22 with the engaging part 22l of the second supporting member 22 inserted into the hole 26d. In detail, the third supporting member 23 is interposed between the base portion 26a and the first supporting member 21. With such a configuration, the sixth supporting member 26 (standing portion 2b) is coupled (fixed) to the grounding portion 2a. The standing wall 26b has an opening 26e. The opening 26e constitutes the opening 2g.

The wall 26b extends upward from the rear end of the base portion 26a. A speaker 14B is attached to the front surface 26c of the wall 26b.

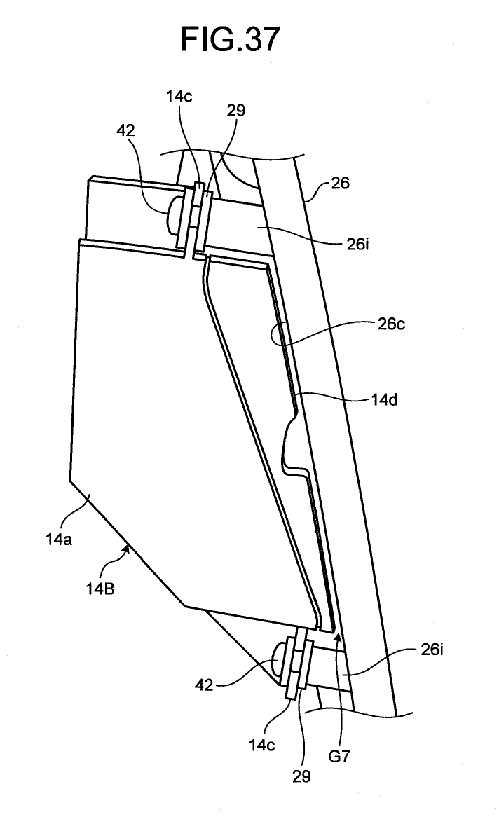

The speaker 14B is a housed component (a component or a member) housed in the standing portion 2b. The speaker 14B faces the housing 3. The speaker 14B may be arranged lower than the housing 3 so as not to face the housing 3. The speaker 14B comprises a cabinet 14a (a housing or a frame) and a unit 14b that is housed and held in the cabinet 14a and that emits sound. The unit 14b faces the rear surface 3b of the housing 3. The unit 14b emits sound toward the front (toward the housing 3). As illustrated in FIG. 37, the cabinet 14a of the speaker 14B comprises an attachment 14c. The attachment 14c is connected (fixed) to a fixing part 26i provided to the front surface 26c of the wall 26b via an intervening member 29 by the fixture 42. The fixing part 26i is a boss in which a screw hole is bored, for example, and the fixture 42 is a screw. The intervening member 29 is an elastic member, for example, and absorbs vibrations of the speaker 14B. A gap G7 is formed between a rear surface 14d of the cabinet 14a and the front surface 26c of the standing wall 26b. With this configuration, it is possible to prevent the vibrations of the speaker 14B from being transmitted to the standing wall 26b.

As illustrated in FIG. 30, the attachment 26c extends from the upper end of the wall 26b toward the front. The attachment 26c has a groove 26g. The shaft 8b of the hinge 8 is inserted into the groove 26g. The groove 26g has a screw hole 26h (a fixing part or a support). The fixture 42 penetrating the shaft 8b is connected to the screw hole 26h, thereby connecting the shaft 8b (hinge 8) to the attachment 26c. As illustrated in FIG. 29, the harness 19 extends from the attachment 26c. The harness 19 is connected to the speaker 14B. At least a part of the attachment 26c is housed in the recess 3ad. In the support 2, the attachment 26c is a section connected to the housing 3 through the opening 3va.

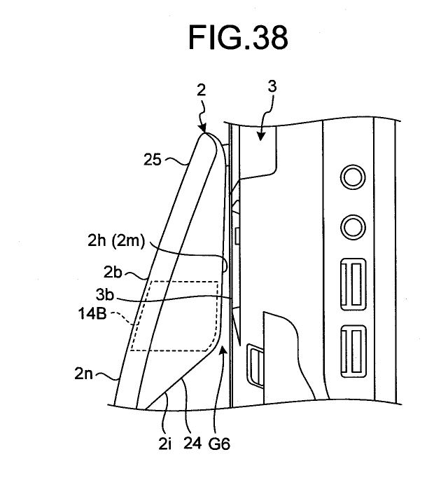

In the present embodiment, as illustrated in FIG. 38, a gap G6 is formed between the first surface 2h of the standing portion 2b and the rear surface 3b of the housing 3 when the rear surface 3b of the housing 3 is positioned closest to the first surface 2h (front surface 2m) of the standing portion 2b in the support 2. In other words, the support 2 supports the housing 3 via the hinge 8 in a rotatable manner such that the housing 3 does not come into contact with the first surface 2h (front surface 2m) of the standing portion 2b.

As described above, in the present embodiment, for example, the wall 33a of the third housing member 33 is arranged with the gap G1 interposed between the wall 33a and the back surface 4b of the display device 4. The opening 33c is provided to the wall 33a, and the air inlet 9a1 of the fan 9 is arranged in a manner overlapped with the opening 33c. Therefore, according to the present embodiment, for example, the air stream St1 flowing along the gap G1 can suppress a rise in temperature of the back surface 4b of the display device 4.

In the present embodiment, for example, the opening 33c is positioned in an eccentric (apart or distant) manner in an upper portion, that is, in a direction toward the side opposite the support 2 with respect to the center of the back surface 4b of the display device 4. Therefore, according to the present embodiment, for example, heated air is unlikely to remain in the gap G1, and is more likely to flow out from the opening 33c. Furthermore, in the present embodiment, for example, the opening 33c is positioned in a middle portion (center portion) between the two corners 3g and 3h (between the ends 3d and 3f). Therefore, for example, deviation in the horizontal direction viewed from the front is unlikely to occur in the air stream St1 in the gap G1. As a result, deviation in temperature distribution is unlikely to occur in the gap G1.

In the present embodiment, for example, the fan 9 and the opening 33c are arranged between the two corners 3g and 3h positioned on the right and left sides of the upper side of the housing 3. Furthermore, in the present embodiment, for example, the vent 43B is provided to the end 3c extending between the two corners 3g and 3h. Therefore, according to the present embodiment, for example, the air heated in the housing 3 can be exhausted more efficiently.

In the present embodiment, for example, the air outlet 9b of the fan 9 is arranged close to one end of the vent 43B, that is, close to the end 43a side. Therefore, according to the present embodiment, for example, air can readily enter the housing 3 from the area on the other end of the vent 43B, that is, on the end 43b side. In other words, for example, the vent 43B can be used as both an inlet and an outlet for the air.

Furthermore, in the present embodiment, for example, the opening 33d is provided to the wall 33a at a position close to the other end of the vent 43B, that is, close to the end 43b side. Therefore, according to the present embodiment, for example, the air that enters the housing 3 from the vent 43B can be readily introduced to the gap G1 from the opening 33d. Accordingly, for example, it is possible to suppress a rise in temperature of the back surface 4b of the display device 4.

In the present embodiment, for example, the vent 43A is provided to the end 3e positioned on the side opposite the end 3c. Therefore, according to the present embodiment, for example, an air stream can be readily generated in the housing 3. Accordingly, for example, it is possible to suppress a rise in temperature in the housing 3.

In the present embodiment, for example, the opening 33e is arranged on the side opposite the vent 43B with respect to the opening 33c in the wall 33b of the third housing member 33. Therefore, according to the present embodiment, for example, air can be further readily introduced to the gap G1. Accordingly, for example, it is possible to further suppress a rise in temperature of the back surface 4b of the display device 4.

In the present embodiment, for example, the vent 43C is arranged on the side wall 44b of the recess 44 provided to the wall 3m. Therefore, according to the present embodiment, for example, the vent 43C can be formed in a more inconspicuous manner. Furthermore, for example, it is possible to further prevent dust or the like from entering the housing 3 from the vent 43C.

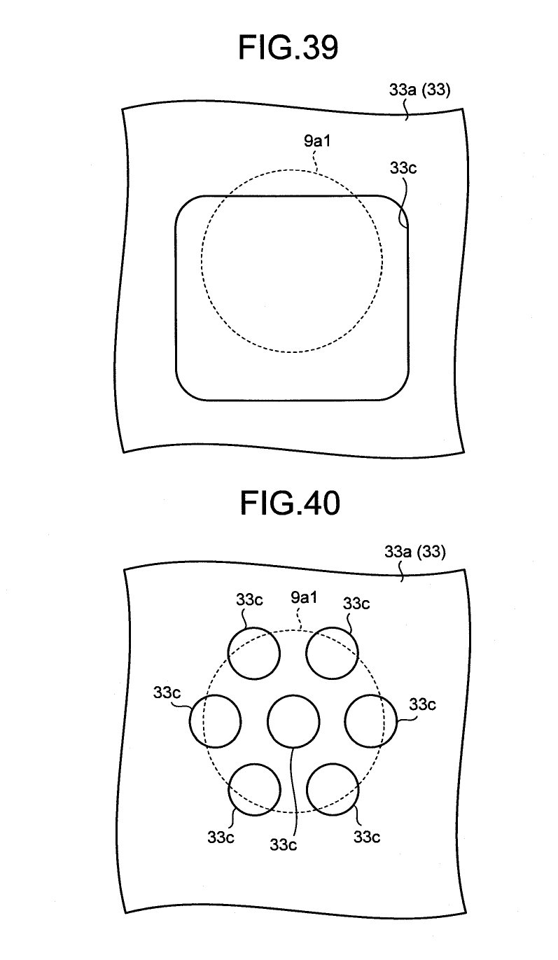

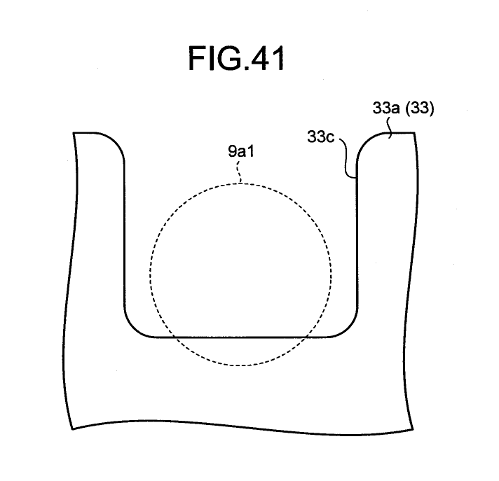

While certain embodiments have been described, these embodiments have been presented by way of example only, and are not intended to limit the scope of the inventions. For example, the novel receivers and apparatuses described herein may be embodied in a variety of other forms. As illustrated in FIGS. 39 to 41, for example, the positional relationship between the air inlet 9a1 of the fan 9 and the opening 33c of the wall 33a can be changed in various manners. In other words, as illustrated in FIG. 39, the opening 33c may be a thorough-hole in a rectangular shape. As illustrated in FIG. 40, the opening 33c may be formed as a group of small apertures, or may be formed in a mesh pattern, which is not illustrated. Alternatively, the opening 33c may be formed as a cutout. Furthermore, as illustrated in FIGS. 39 to 41, the opening 33c and the air inlet 9a1 need to be overlapped with each other at least partially. The proportion of the overlapping portion in the opening 33c and the air inlet 9a1 can be changed in various manners. The technological characteristics in the embodiments and the modifications can be combined as appropriate. Furthermore, the specifications (e.g., structure, type, direction, shape, size, length, width, thickness, height, number, arrangement, position, and material) of each of the components can be changed as appropriate.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television receiver comprising:
a display comprising a display screen and a back surface opposite the display screen;
a housing comprising a first wall covering the back surface, the housing configured to house at least part of the display;
a stand configured to connect to the housing, and to support the housing;
a circuit board comprising a surface on which a heating element is mounted, the circuit board between the display and the first wall;
a second wall comprising an opening eccentrically positioned in a direction toward a side opposite the stand with respect to a center portion of the display screen, the second wall between the display and a surface of the circuit board opposite the surface on which the heating element is mounted, the second wall configured to cover the back surface with a gap between the second wall and the back surface;
a fan between the first wall and the second wall, the fan comprising an air inlet overlapping at least part of the opening; and
a heat dissipater configured to thermally connect to the heating element, and to receive exhaust air from the fan.

2. The television receiver of claim 1, further comprising:
a support configured to support the housing, wherein
the housing comprises two corners positioned on right and left sides of an upper side of the house when viewing the display screen from a front and the support is on a horizontal surface, and
the fan and the opening are between the two corners.

3. The television receiver of claim 2, wherein the housing comprises a second opening at a first end portion extending between the two corners.

4. The television receiver of claim 3, wherein an air outlet of the fan is close to a first end of the second opening.

5. The television receiver of claim 4, wherein the second wall comprises a third opening, the third opening close to a second end of the second opening.

6. The television receiver of claim 3, wherein a second end portion comprises a fourth opening, the fourth opening positioned opposite the first end portion.

7. The television receiver of claim 3, further comprising:
a member comprising the second wall and a third wall covering a side surface extending between the display screen and the back surface of the display, wherein
the third wall comprises a fifth opening at a side opposite the second opening with respect to the opening.

8. The television receiver of claim 1, wherein
the first wall comprises a recess,
the recess is configured to recess toward the display screen,
the recess comprises a bottom wall and a side wall extending between the bottom wall and the first wall, and
the side wall comprises a sixth opening.

9. An electronic device comprising:
a display comprising a display screen and a back surface opposite the display screen;
a housing comprising a first wall covering the back surface, the housing configured to house at least part of the display;
a circuit board between the display and the first wall;
a second wall comprising an opening, the second wall between the display and the circuit board, the second wall configured to cover the back surface with a gap therebetween; and
a fan between the first wall and the second wall, the fan comprising an air inlet overlapping at least part of the opening.

10. An electronic device comprising:
a display;
a housing configured to cover at least part of the display;
a wall in the housing, the wall comprising a first opening, the wall separated from the display; and
a fan comprising a second opening overlapping at least part of the first opening.
